(19) United States
(12) Patent Application Publication
(10) Pub. No.: US 2021/0277157 A1
(43) Pub. Date: Sep. 9, 2021

(54) VINYLETHER-BASED POLYMER AS DIELECTRIC

(71) Applicant: Clap Co., Ltd., Seoul (KR)

(72) Inventors: Daniel KAELBLEIN, Ludwigshafen (DE); Fulvio Giacomo BRUNETTI, Ludwigshafen (DE); Georg BECK, Ludwigshafen (DE); Daniel BAHL, Ludwigshafen (DE); Ulrich BERENS, Ludwigshafen (DE); Ingo MUENSTER, Ludwigshafen (DE)

(73) Assignee: Clap Co., Ltd., Seoul (KR)

(21) Appl. No.: 17/255,397

(22) PCT Filed: May 22, 2019
(86) PCT No.: PCT/EP2019/063198

§ 371 Date: Dec. 22, 2020

(30) Foreign Application Priority Data
Jun. 26, 2018 (EP) 18179713.5

(51) Int. Cl. C08F 216/14; C08F 212/14

(52) U.S. Cl. CPC C08F 216/1416; H01L 51/052; C08F 212/22

(57) ABSTRACT

The present invention provides polymers comprising units of formula (1) as well as compositions comprising the polymers, processes for the preparation of the polymers, electronic devices comprising the polymers, and processes for the preparation of the electronic devices, and the use of the polymers as dielectric materials.

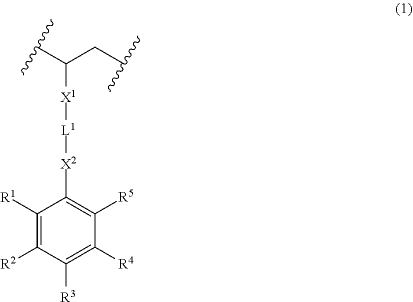

The present invention relates to vinyl-ether based polymers, compositions comprising the polymers, processes for the preparation of the polymers, electronic devices comprising the polymers, and processes for the preparation of the electronic devices, and the use of the polymers as dielectric materials.

Dielectric materials can be applied in many electronic devices such as field effect transistors (FETs). Field effect transistors (FETs) can be used in applications that require electronic functionalities such as displays, large-area sensors and radio-frequency identification (RFID) tags.

Field effect transistors contain a semiconducting layer that is separated from the gate electrode by a thin dielectric layer. When voltage is applied between the gate electrode and an electrode attached to the semiconductor, e.g. the source electrode, a thin sheet of mobile electronic charges is created in the semiconductor in close vicinity of the semiconductor/dielectric interface. This charge layer balances the charge (of opposite polarity) located on the gate electrode. By tuning the gate-source voltage, the charge density in the semiconductor channel can be modulated over a wide range and as a result the electric conductivity of the charge-carrier channel changes dramatically. With another electrode attached to the semiconductor (the drain electrode), the electric current flowing through the transistor from the source to the drain electrode can therefore be efficiently controlled over a wide range, simply by adjusting the qate-source voltage.

Field-effect transistors suitable for portable or handheld devices powered by small batteries or by near-field radio-frequency coupling should ideally show a high drain-current at low gate-source voltage operation. A high drain current at low gate-source voltage can be achieved by using a dielectric layer with a large capacitance which also ensures that the carrier density in the channel is controlled by the gate-source voltage and not by the drain-source voltage, which is especially critical for field effect transistors with short channel length. Thus, it is desirable that the dielectric material forming the dielectric layer yields a large capacitance and field-effect transistors that can be operated at low gate-source voltage.

It is also desirable that the dielectric material forming the dielectric layer is an organic material which is compatible with liquid processing techniques such as spin coating as liquid processing techniques allow the production of low cost electronic devices comprising field-effect transistors. In addition, liquid processing techniques are also compatible with plastic substrates, and thus allow the production of light weight and mechanically flexible electronic devices comprising field effect transistors.

Polystyrene is a common dielectric material for use in organic field effect transistors. However, organic field effect transistors comprising polystyrene as dielectric material do not yield high drain currents at low gate-source voltage operation due to the relatively low dielectric constant of polystyrene, and thus do not favor transistor to be operated at low gate-source voltage.

US20140004464 describes photoresist compositions, also used for forming electronic devices, comprising copolymers made from an acrylate monomer (I), acyclic vinyl ether monomer (II) and cyclic vinyl ether monomer (III). An example of (II) is fluorinated 2-(2-vinyloxyethoxy)naphthalene.

It was the object of the present invention to provide dielectric materials suitable for preparing the dielectric layer in a field effect transistor, which transistor can be operated at low gate-source voltage.

This object is solved by the polymer of claim 1, the processes for the preparation of the polymers of claims 12 and 13, the composition comprising the polymers of claim 14, the electronic device of claim 16, the process for the preparation of the electronic device of claim 18 and the use of the polymer as dielectric material of claim 19.

The polymers of the present invention are polymers comprising units of formula (1)

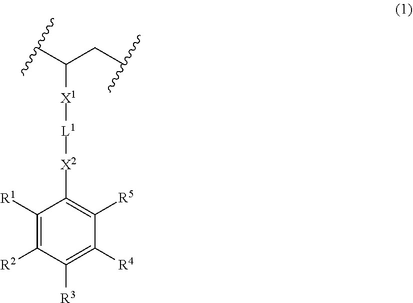

wherein
X¹ and X² are independently O or S,
L¹ is a linking group, and
R¹, R², R³, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, C(O)—C₆₋₁₄-aryl substituted with one or more substituents R^{b}, 5 to 14 membered heteroaryl and 5 to 14 membered heteroaryl substituted with one or more substituents R^{b},
or
R¹ and R² together with the C-atoms to which they are attached form a 5 to 6 membered ring or a 5 to 6 membered ring substituted with one or more substituents R^{c}, and
R³, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, C(O)—C₆₋₁₄-aryl substituted with one or more substituents R^{b}, 5 to 14 membered heteroaryl and 5 to 14 membered heteroaryl substituted with one or more substituents R^{b},
or
R² and R³ together with the C-atoms to which they are attached form a 5 to 6 membered ring or a 5 to 6 membered ring substituted with one or more substituents R^{c}, and
R¹, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, C(O)—C₆₋₁₄-aryl substituted with one or more substituents R^{b}, 5 to 14 membered heteroaryl and 5 to 14 membered heteroaryl substituted with one or more substituents R^{b},
or
R³ and R⁴ together with the C-atoms to which they are attached form a 5 to 6 membered ring or a 5 to 6 membered ring substituted with one or more substituents R^{c}, and
R¹, R² and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, C(O)—C₆₋₁₄-aryl substituted with one or more substituents R^{b}, 5 to 14 membered heteroaryl and 5 to 14 membered heteroaryl substituted with one or more substituents R^{b},
or
R⁴ and R⁵ together with the C-atoms to which they are attached form a 5 to 6 membered ring or a 5 to 6 membered ring substituted with one or more substituents R^{c}, and
R¹, R² and R³ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, C(O)—C₆₋₁₄-aryl substituted with one or more substituents R^{b}, 5 to 14 membered heteroaryl and 5 to 14 membered heteroaryl substituted with one or more substituents R^{b},
wherein
R^{a} is at each occurrence selected from the group consisting of O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, C(O)-phenyl and 5 to 9 membered heteroaryl, and
R^{b} and R^{c} are independently and at each occurrence selected from the group consisting of C₁₋₂₀-alkyl, O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, C(O)-phenyl and 5 to 9 membered heteroaryl.

C₁₋₆-alkyl, C₁₋₁₀-alkyl, C₁₋₂₀-alkyl, C₁₋₃₀-alkyl and C₆₋₃₀-alkyl can be branched or unbranched. Examples of C₁₋₆-alkyl are methyl, ethyl, n-propyl, isopropyl, n-butyl, sec-butyl, isobutyl, tert-butyl, n-pentyl, neopentyl, isopentyl, n-(2,2-dimethyl)propyl, n-(1-ethyl)propyl and n-hexyl. Examples of C₁₋₁₀-alkyl are C₁₋₆-alkyl and n-heptyl, 2-heptyl, n-octyl, 2-octyl, n-(3-methyl)heptyl, n-(1,1,3,3-tetramethyl)butyl, n-(2-ethyl)hexyl, n-nonyl, n-(1,1,3,3-tetramethyl)pentyl and n-decyl. Examples of C₁₋₂₀-alkyl are C₁₋₁₀-alkyl and n-undecyl, n-dodecyl, n-undecyl, n-dodecyl, n-tridecyl, n-tetradecyl, n-pentadecyl, n-hexadecyl, n-heptadecyl, n-octadecyl, n-nonadecyl and n-icosyl (C₂₀). Examples of C₁₋₃₀-alkyl are C₁₋₂₀-alkyl and n-docosyl (C₂₂), n-tetracosyl (C₂₄), n-hexacosyl (C₂₆), n-octacosyl (C₂₈) and n-triacontyl (C₃₀). Examples of C₆₋₃₀-alkyl are n-hexyl, n-heptyl, 2-heptyl, n-octyl, 2-octyl, n-(3-methyl)heptyl, n-(1,1,3,3-tetramethyl)butyl, n-(2-ethyl)hexyl, n-nonyl, n-(1,1,3,3-tetramethyl)pentyl and n-decyl n-undecyl, n-dodecyl, n-undecyl, n-dodecyl, n-tridecyl, n-tetradecyl, n-pentadecyl, n-hexadecyl, n-heptadecyl, n-octadecyl, n-nonadecyl, n-icosyl (C₂₀), n-docosyl (C₂₂), n-tetracosyl (C₂₄), n-hexacosyl (C₂₆), n-octacosyl (C₂₈) and n-triacontyl (C₃₀)

Examples of C₅₋₆-cycloalkyl are cyclopentyl and cyclohexyl. Examples of C₅₋₇-cycloalkyl are C₅₋₆-cycloalkyl and cycloheptyl.

C₆₋₁₄-aryl is a monovalent aromatic ring system, consisting of one aromatic ring or of two or three condensed aromatic rings, wherein all rings are formed from carbon atoms. Examples of C₆₋₁₄-aryl are

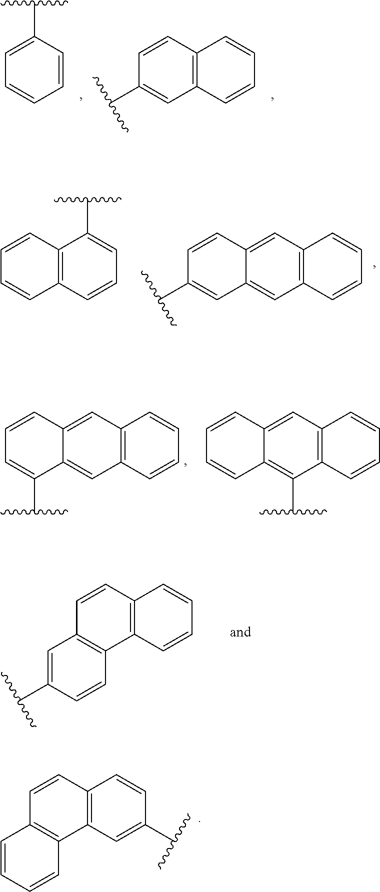

5 to 9 membered heteroaryl is a monovalent aromatic ring system consisting of one aromatic ring or of two condensed aromatic rings, wherein at least one aromatic ring contains at least one heteroatom selected from the group consisting of S, O, N and Se.

Examples of 5 to 9 membered heteroaryl are

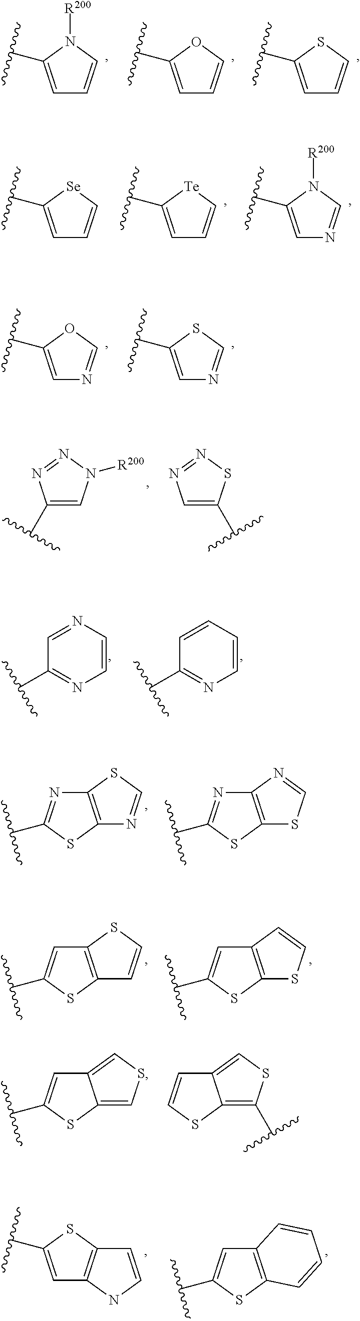

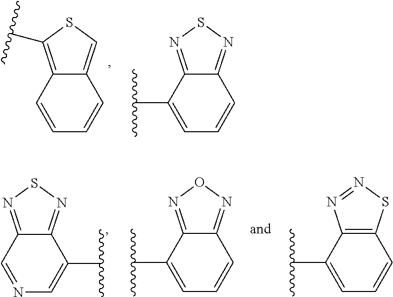

wherein R²⁰⁰ is H or C₁₋₂₀-alkyl.

5 to 14 membered heteroaryl is a monovalent aromatic ring system consisting of one aromatic ring or of two to four condensed aromatic rings, wherein at least one aromatic ring contains at least one heteroatom selected from the group consisting of S, O, N and Se. Examples of 5 to 14 membered heteroaryl are 5 to 9 membered heteroaryl and

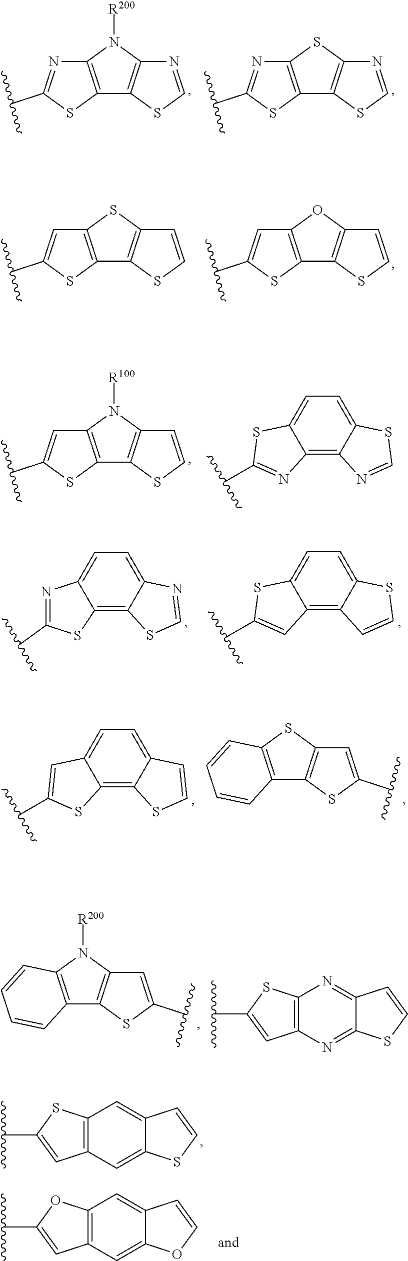

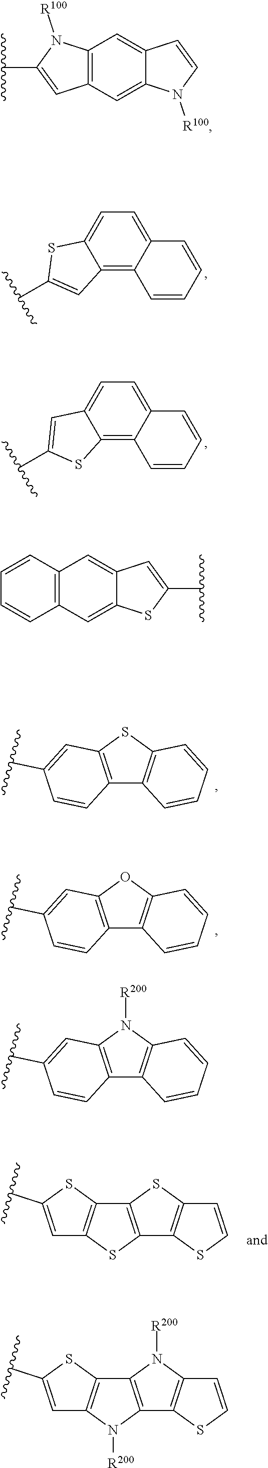

wherein R²⁰⁰ is H or C₁₋₂₀-alkyl.

A 5 or 6 membered ring can be an aromatic or heteroaromatic 5 or 6 membered ring contains at least one heteroatom selected from the group consisting of S, O, N and Se, or an alicyclic 5 to 6 membered ring, wherein one or two CH₂ groups can be replaced by O, S or NR³⁰⁰, wherein R³⁰⁰ is C₁₋₂₀-alkyl.

Examples of aromatic and heteroaromatic 5 to 6 membered rings are

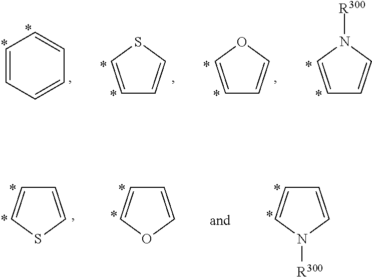

wherein R³⁰⁰ is C₁₋₂₀-alkyl, and the C-atoms marked with * are the C-atoms to which R¹ and R², R² and R³, R³ and R⁴, and R⁴ and R⁵, respectively, are attached.

Examples of alicyclic 5 to 6 membered rings, wherein one or two CH₂ groups can be replaced by O, S or NR³⁰⁰, wherein R³⁰⁰ is C₁₋₂₀-alkyl, are

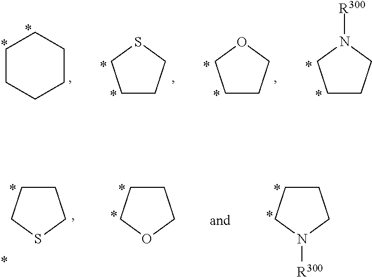

wherein R³⁰⁰ is C₁₋₂₀-alkyl, and the C-atoms marked with * are the C-atoms to which R¹ and R², R² and R³, R³ and R⁴, and R⁴ and R⁵, respectively, are attached.

C₁₋₄-alkylene, C₁₋₁₀-alkylene and C₁₋₃₀-alkylene can be branched or unbranched. Examples of C₁₋₄-alkylene are methylene, ethylene, propylene and butylene. Examples of C₁₋₁₀-alkylene are C₁₋₄-alkylene and pentylene, hexylene, heptylene, octylene, nonylene and decylene. Examples of C₁₋₃₀-alkylene are C₁₋₁₀-alkylene and undecylene, dodecylene, tridecylene, tetradecylene, pentadecylene, hexadecylene, heptadecylene, octadecylene, nonadecylene and icosylene (C₂₀).

Examples of C₅₋₇-cycloalkylene are cyclopentylene, cyclohexylene and cycloheptylene.

Examples of halogen are F, Cl, Br and I.

Preferably, X¹ and X² are O.

Preferably, L¹ is a linking group selected from the group consisting of C₁₋₃₀-alkylene, C₁₋₁₀-alkylene-phenylene-C₁₋₁₀-alkylene, C₁₋₁₀-alkylene-C₅₋₇-cycloalkylene-C₁₋₁₀-alkylene, phenylene and C₅₋₇-cycloalkylene. More preferably, L¹ is a linking group, which is C₁₋₃₀-alkylene. Even more preferably, L¹ is a linking group which is of C₁₋₁₀-alkylene. Most preferably, L¹ is a linking group which is of C₁₋₄-alkylene.

Preferably,

R¹, R², R³, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, and C(O)—C₆₋₁₄-aryl substituted with one or more substituents R^{b},
or
R¹ and R² together with the C-atoms to which they are attached form a 5 to 6 membered ring or a 5 to 6 membered ring substituted with one or more substituents R^{c}, and
R³, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, and C(O)—C₆₋₁₄-aryl substituted with one or more substituents R^{b},
or
R² and R³ together with the C-atoms to which they are attached form a 5 to 6 membered ring or a 5 to 6 membered ring substituted with one or more substituents R^{c}, and
R¹, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, and C(O)—C₆₋₁₄-aryl substituted with one or more substituents R^{b},
or
R³ and R⁴ together with the C-atoms to which they are attached form a 5 to 6 membered ring or a 5 to 6 membered ring substituted with one or more substituents R^{c}, and
R¹, R² and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, and C(O)—C₆₋₁₄-aryl substituted with one or more substituents R^{b},
or
R⁴ and R⁵ together with the C-atoms to which they are attached form a 5 to 6 membered ring or a 5 to 6 membered ring substituted with one or more substituents R^{c}, and
R¹, R² and R³ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, and C(O)—C₆₋₁₄-aryl substituted with one or more substituents R^{b},
wherein
R^{a} is at each occurrence selected from the group consisting of O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, and C(O)-phenyl, and
R^{b} and R^{c} are at each occurrence selected from the group consisting of C₁₋₂₀-alkyl, O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, and C(O)-phenyl.

More preferably,

R¹, R, R³, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, and C(O)—C₁₋₃₀-alkyl substituted with one or more substituents R^{a},
or
R¹ and R² together with the C-atoms to which they are attached form a 5 to 6 membered aromatic ring or a 5 to 6 membered aromatic ring substituted with one or more substituents R^{c}, and
R³, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, and C(O)—C₁₋₃₀-alkyl substituted with one or more substituents R^{a},
or
R² and R³ together with the C-atoms to which they are attached form a 5 to 6 membered aromatic ring or a 5 to 6 membered aromatic ring substituted with one or more substituents R^{c}, and
R¹, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, and C(O)—C₁₋₃₀-alkyl substituted with one or more substituents R^{a},
or
R³ and R⁴ together with the C-atoms to which they are attached form a 5 to 6 membered aromatic ring or a 5 to 6 membered aromatic ring substituted with one or more substituents R^{c}, and
R¹, R² and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a},
or
R⁴ and R⁵ together with the C-atoms to which they are attached form a 5 to 6 membered aromatic ring or a 5 to 6 membered aromatic ring substituted with one or more substituents R^{c}, and
R¹, R² and R³ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a},
wherein
R^{a} is at each occurrence selected from the group consisting of O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, and C(O)-phenyl, and
R^{c} is at each occurrence selected from the group consisting of C₁₋₂₀-alkyl, O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, and C(O)-phenyl.

Even more preferably,

R¹, R², R³, R⁴ and R³ are independently selected from the group consisting of H, C₁₋₁₀-alkyl and O—C₁₋₁₀-alkyl,
or
R¹ and R² together with the C-atoms to which they are attached form an aromatic 6-membered aromatic ring, which is

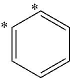

wherein the C-atoms marked with * are the C-atoms to which R¹ and R² are attached, and
R³, R⁴ and R⁵ are independently selected from the group consisting of H, C₁₋₁₀-alkyl and O—C₁₋₁₀-alkyl,
or
R² and R³ together with the C-atoms to which they are attached form an aromatic 6-membered aromatic ring, which is

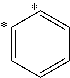

wherein the C-atoms marked with * are the C-atoms to which R² and R³ are attached, and
R¹, R⁴ and R⁵ are independently selected from the group consisting of H, C₁₋₁₀-alkyl and O—C₁₋₁₀-alkyl,
or
R³ and R⁴ together with the C-atoms to which they are attached form an aromatic 6-membered aromatic ring, which is

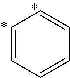

wherein the C-atoms marked with * are the C-atoms to which R³ and R⁴ are attached, and
R¹, R² and R⁵ are independently selected from the group consisting of H, C₁₋₁₀-alkyl and O—C₁₋₁₀-alkyl,
or
R⁴ and R⁵ together with the C-atoms to which they are attached form an aromatic 6-membered aromatic ring, which is

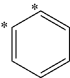

wherein the C-atoms marked with * are the C-atoms to which R⁴ and R⁵ are attached, and
R¹, R², and R³ are independently selected from the group consisting of H, C₁₋₁₀-alkyl and O—C₁₋₁₀-alkyl.

Most preferably,

R¹, R % R³, R⁴ and R⁵ are independently selected from the group consisting of H, C₁₋₁₀-alkyl and O—C₁₋₁₀-alkyl,
or
R² and R³ together with the C-atoms to which they are attached form an aromatic 6-membered aromatic ring, which is

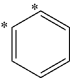

the C-atoms marked with * are the C-atoms to which R² and R³ are attached, and
R¹, R⁴ and R⁵ are independently selected from the group consisting of H, C₁₋₁₀-alkyl and O—C₁₋₁₀-alkyl,
or
R³ and R⁴ together with the C-atoms to which they are attached form an aromatic 6-membered aromatic ring, which is

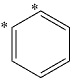

wherein the C-atoms marked with * are the C-atoms to which R³ and R⁴ are attached, and
R¹, R² and R⁵ are independently selected from the group consisting of H, C₁₋₁₀-alkyl and O—C₁₋₁₀-alkyl.

Preferred units of formula (1) are units of formulae

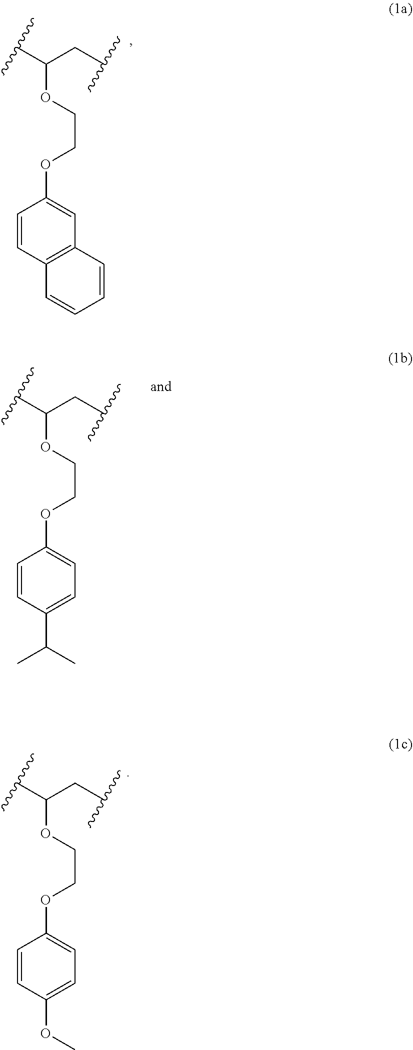

Preferred polymers of the present invention also comprise units of formula (2)

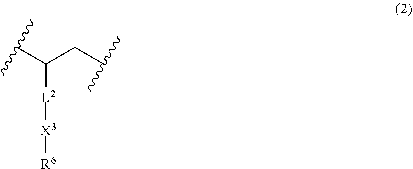

wherein
X³ is independently O or S,
L² is a covalent bond or a linking group,
R⁶ is independently selected from the group consisting of H, C₁₋₃₀-alkyl, C₁₋₃₀-alkyl substituted with one or more substituents R^{d}, C₅₋₇-cycloalkyl, C₅₋₇-cycloalkyl substituted with one or more substituents R^{e}, C₆₋₁₄-aryl, C₆₋₁₄-aryl substituted with one or more substituents R^{e}, 5 to 14 membered heteroaryl and 5 to 14 membered heteroaryl substituted with one or more substituents R^{e},
wherein
R^{d} is at each occurrence selected from the group consisting of O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, C(O)-phenyl and 5 to 9 membered heteroaryl, and
R^{e} is at each occurrence selected from the group consisting of C₁₋₂₀-alkyl, O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, C(O)-phenyl and 5 to 9 membered heteroaryl.

### Preferably, X³ is O.

Preferably, L² is a covalent bond or a linking group selected from the group consisting of C₁₋₃₀-alkylene, C₁₋₁₀-alkylene-phenylene-C₁₋₁₀-alkylene, C₁₋₁₀-alkylene-C₅₋₇-cycloalkylene-C₁₋₁₀-alkylene, phenylene and C₅₋₇-cycloalkylene. More preferably, L² is a covalent bond or a linking group, which is phenylene.

Preferably,

R⁶ is independently selected from the group consisting of H, C₁₋₃₀-alkyl, C₁₋₃₀-alkyl substituted with one or more substituents R^{d}, C₅₋₇-cycloalkyl, C₅₋₇-cycloalkyl substituted with one or more substituents R^{e}, C₆₋₁₄-aryl, and C₆₋₁₄-aryl substituted with one or more substituents R^{e},
wherein
R^{d} is at each occurrence selected from the group consisting of O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, and O-phenyl, C(O)-phenyl, and
R^{e} is at each occurrence selected from the group consisting of C₁₋₂₀-alkyl, O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, and C(O)-phenyl.
   More preferably,
   R⁶ is independently selected from the group consisting of H, C₁₋₃₀-alkyl, C₁₋₃₀-alkyl substituted with one or more substituents R^{d}, C₅₋₇-cycloalkyl, and C₅₋₇-cycloalkyl substituted with one or more substituents R^{e}, wherein
R^{d} is at each occurrence selected from the group consisting of O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, and O-phenyl, C(O)-phenyl, and
R^{e} is at each occurrence selected from the group consisting of C₁₋₂₀-alkyl, O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, and C(O)-phenyl.

Even more preferably,

R⁶ is independently selected from the group consisting of H, C₁₋₁₀-alkyl and C₅₋₇-cycloalkyl.

Preferred units of formula (2) are units of formula

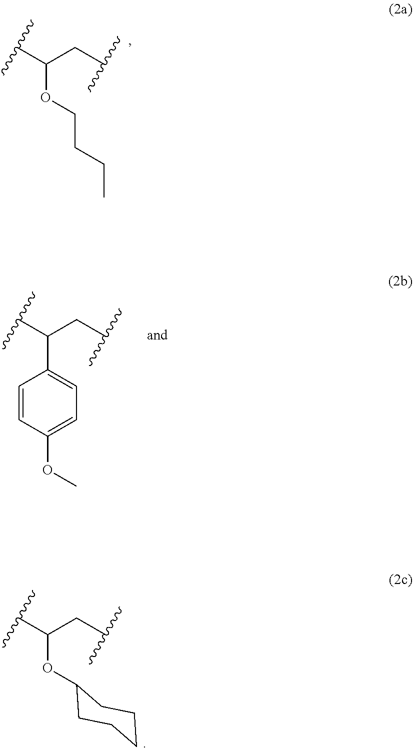

Particular preferred polymers of the present invention are of formulae

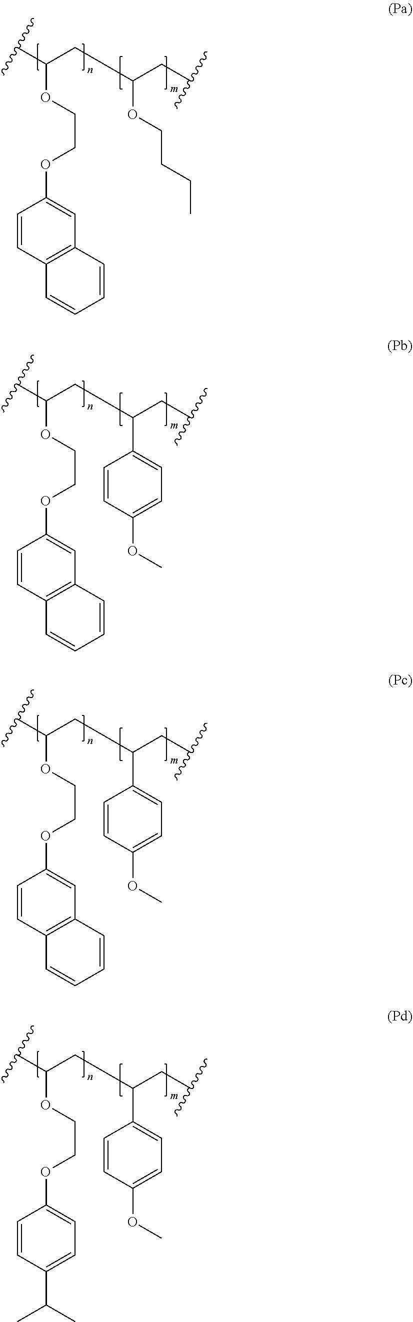

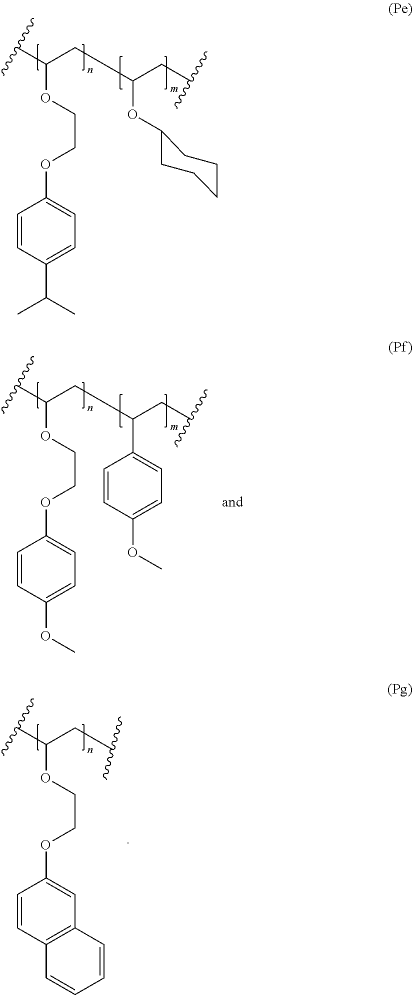

The polymers of the present invention comprise at least 3 mol %, preferably at least 10 mol % units of formula (1) based on the mols of all repeating units of the polymer of the present invention.

The polymers of the present invention usually have a number average molar mass Mn of at least 10000 g/mol, preferably at least 20000 g/mol, more preferably at least 40000 g/mol, most preferably at least 250000 g/mol.

The polymers of the present invention usually have a z-average molar mass Mz of at least 40000 g/mol, preferably at least 90000 g/mol, more preferably at least 150000 g/mol, most preferably at least 500000 g/mol.

Polymers of the present invention comprising units of formulae (1) and (2) comprise at least 50 mol %, preferably at least 70 mol %, more preferably at least 80 mol %, even more preferably at least 90 mol % units of formula (1) and (2) based on the mols of all repeating units of the polymer of the present invention. Most preferably, polymers of the present invention comprising units of formulae (1) and (2) essentially consist of units of formula (1) and (2), meaning comprising at least 95 mol % units of formula (1) and (2).

Polymers of the present invention comprising units of formulae (1) and (2) usually comprise the units of formulae (1) and (2) in a molar ratio of 20:1 to 1:30, preferably in a molar ratio of 10:1 to 1:20, more preferably in a molar ratio of 6:1 to 1:5, even more preferably in a molar ratio of 6:1 to 1:1 most preferably in a molar ratio of 6:1 to 3:1.

Also, part of the present invention is a process for the preparation of the polymers of the present invention. The process for the preparation of the polymers of the present invention comprising units of formula (1)

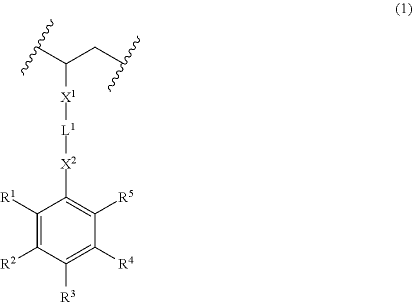

wherein
X¹ and X², L¹ and R¹, R², R³, R⁴ and R⁵ are as defined above, comprises the step of polymerizing monomers including the compound of formula (3)

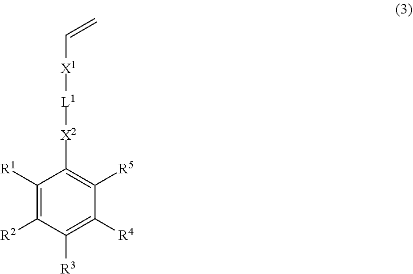

wherein
X¹, X², L¹, R¹, R², R³, R⁴ and R⁵ are as defined fora compound of formula (1), in order to yield the polymers of the present invention.

The process for the preparation of the polymers of the present invention comprising units of formula (1) and units of formula (2)

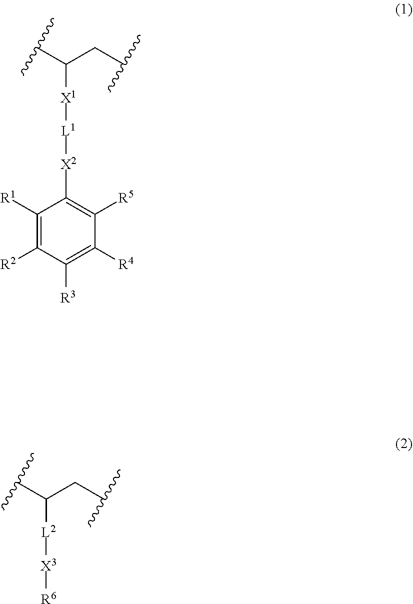

wherein
X¹, X², L¹, R¹, R², R³, R⁴ and R⁵ as well as X³, L² and R⁶ are as defined above, comprises the step of polymerizing monomers including the compound of formula (3) and the compound of formula (4)

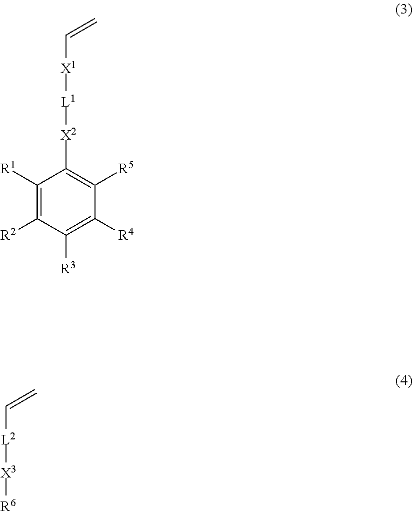

wherein
X¹, X², L¹, R¹, R², R³, R⁴ and R⁵ are as defined fora compound of formula (1), and X³, L² and R⁶ are as defined for the compound of formula (2),
in order to yield the polymers of the present invention.

The monomers can be polymerized by radical, cationic or anionic polymerization.

Preferably, the monomers are polymerized by cationic polymerization. The cationic polymerization is usually performed in the presence of a mineral acid such as H₂SO₄ or H₃PO₄ or mixtures thereof, or, and preferably, in the presence of a Lewis acid such as AlCl₃, BF₃, TiCl₄ or SnCl₄ or mixtures thereof. The sum of all Lewis acids is usually 0.1 to 10% mol based on the mols of all monomers. The cationic polymerization is usually performed in a polar solvent or solvent mixtures. Examples of polar solvents are tetrachloromethane, and, preferably, dichloromethane. The polymerization is usually performed at a temperature of from −50 to 50° C., preferably, at a temperature of from −40 to 0° C.

The compound of formula (3)

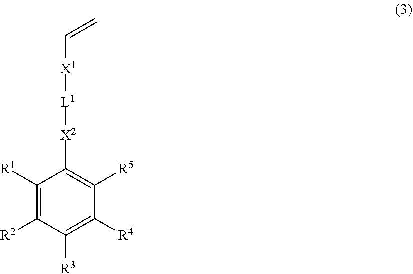

wherein
X¹, X², L¹, R¹, R², R³, R⁴ and R⁵ are as defined above, can be prepared by reacting a compound of formula (8) with a compound of formula (9)

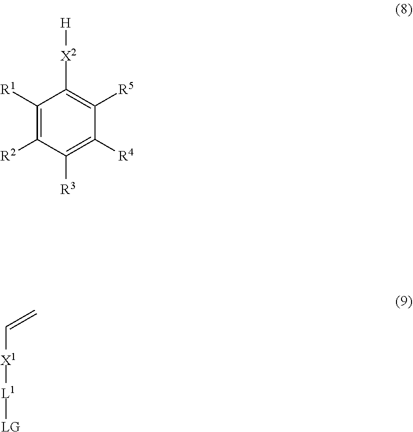

wherein
X¹, X², L¹, R¹, R², R³, R⁴ and R⁵ are as defined for a compound of formula (3), and LG is a leaving group. Examples of leaving groups are halogen such as F, Cl, Br and I, as well as OSO₂CF₃, O-tosyl, O-mesyl and O-phenyl. Preferably, the leaving group is halogen, more preferably Cl or Br.

Compounds of formula (8) and (9) are usually reacted in an apolar aprotic solvent, for example dimethyl formamide, in the presence of a suitable base such as K₂CO₃. Usually the reaction is performed at elevated temperature such as at a temperature in the range of 50 to 150° C.

Also, part of the present invention is a composition comprising at least one polymer of the present invention and a solvent. Preferably, the solvent is a polar aprotic solvent or mixture of polar aprotic solvents. Examples of polar aprotic solvents are ethyl acetate, butyl acetate, acetone, cyclopentanone, tetrahydrofuran, propylene glycol monomethyl ether acetate, acetonitrile, dimethylformamide and dimethyl sulfoxide. Preferred polar aprotic solvents are butyl acetate, cyclopentanone and propylene glycol monomethyl ether acetate. The most preferred organic solvent is butyl acetate. The composition usually comprises 1 to 20% by weight, preferably 5 to 15% by weight, of the polymer of the present invention based on the weight of the composition. The composition is preferably a solution.

The composition can also contain at least one crosslinking agent. Preferably, the crosslinking agent carries least two azide groups, more preferably the crosslinking agent carries two azide groups. Preferably, the crosslinking agent carrying two azide groups is of formula

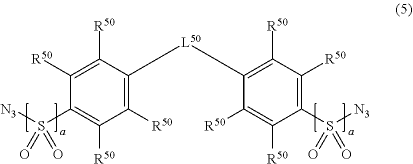

wherein
a is 0 or 1,
R⁵⁰ is at each occurrence selected from the group consisting of H, halogen, SO₃M and C₁₋₂₀-alkyl, which C₁₋₂₀-alkyl can be substituted with one or more halogen,
wherein M is H, Na, K or Li, and
   L⁵⁰ is a linking group.

Preferably, a is 0.

Preferably, R⁵⁰ is at each occurrence selected from the group consisting of F, SO₃M and C₁₋₂₀-alkyl, which C₁₋₂₀-alkyl can be substituted with one or more F, wherein M is Na, K or Li.

More preferably, R⁵⁰ is at each occurrence F.

L⁵⁰ can be any suitable linking group.

Preferably, L⁵⁰ is a linking group of formula

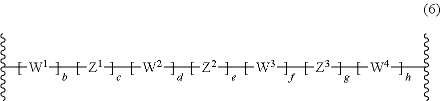

wherein
b, c, d, e, f, g and h are independently from each other 0 or 1, provided that b, c, d, e, f, g and h are not all at the same time 0,
W¹, W², W³ and W⁴ are independently selected from the group consisting of C(O), C(O)O, C(O)—NR⁵¹, SO₂—NR⁵¹, NR⁵¹, N⁺R⁵¹R⁵¹, CR⁵¹═CR⁵¹ and ethynylene
wherein
R⁵¹ is at each occurrence H or C₁₋₁₀-alkyl, or two R⁵¹ groups, which can be from different W¹, W², W³ and W⁴ groups, together with the connecting atoms form a 5, 6 or 7 membered ring, which may be substituted with one to three C₁₋₆-alkyls,
   Z¹, Z² and Z³ are independently selected from the group consisting of C₁₋₁₀-alkylene, C₅₋₇-cycloalkylene, C₆₋₁₄-arylene, 5 to 14 membered heteroarylene and a polycyclic system containing at least one ring selected from C₆₋₁₄-aromatic ring and 5 to 14 membered heteroaromatic ring,
wherein
C₁₋₁₀-alkylene, C₅₋₇-cycloalkylene, C₆₋₁₄ membered arylene, 5 to 14 membered heteroarylene and polycyclic system containing at least one ring selected from C₆₋₁₄-aromatic ring and 5 to 14 membered heteroaromatic ring can be substituted with one to five C₁₋₂₀-alkyl or phenyl.

C₆₋₁₄-arylene is a bivalent aromatic ring system, consisting of one aromatic ring or of two or three condensed aromatic rings, wherein all rings are formed from carbon atoms. Examples of C₆₋₁₄-arylene are

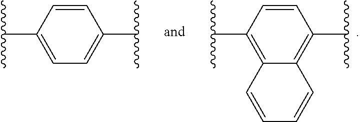 [SMILES: *c1ccc(*)cc1 ; *c1ccc(*)c2ccccc12]

5 to 14 membered heteroarylene is a bivalent aromatic ring system consisting of one aromatic ring or of two to four condensed aromatic rings, wherein at least one aromatic ring contains at least one heteroatom selected from the group consisting of S, O, N and Se. Examples of 5 to 14 membered heteroarylene are

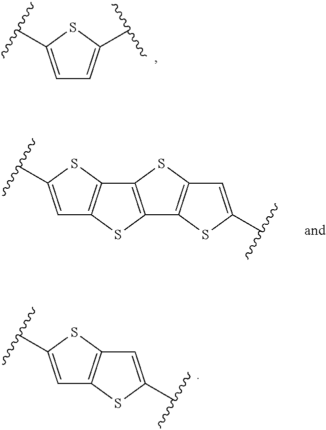 [SMILES: *c1ccc(*)s1 ; *c1cc2sc3c4sc(*)cc4sc3c2s1 ; *c1cc2sc(*)cc2s1]

An example of a polycyclic system containing at least one ring selected from the group consisting of C₆₋₁₄-aromatic ring and 5 to 14 membered heteroaromatic ring is

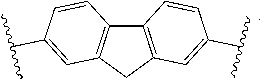 [SMILES: *c1ccc2c(c1)Cc1cc(*)ccc1-2]

Examples of linking groups L⁵⁰ are

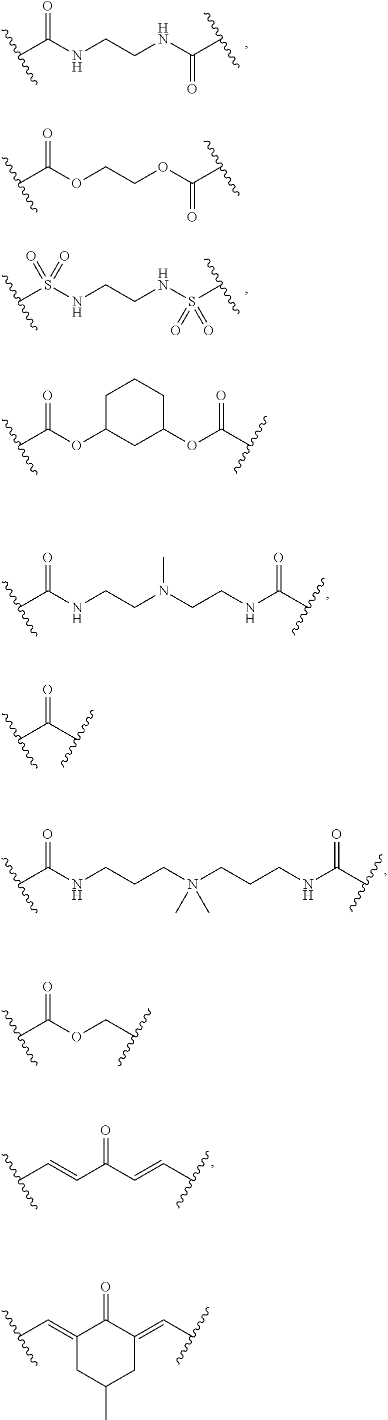

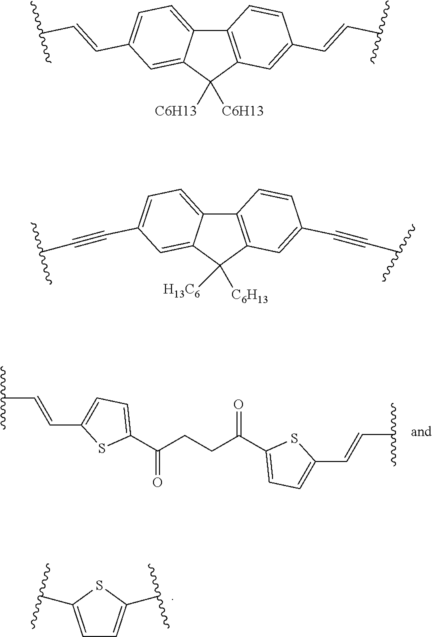

More preferably, L⁵⁰ is a linking group of formula

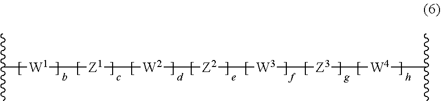

wherein
b, c, d, e, f, g and h are independently from each other 0 or 1, provided that at least one of c, e, and g is 1,
W¹, W², W³ and W⁴ are independently from each other selected from the group consisting of C(O), C(O)O, C(O)—NR⁵¹, SO₂—NR⁵¹, NR⁵¹, N⁺R⁵¹R⁵¹, CR⁵¹═CR⁵¹ and ethynylene
wherein
R⁵¹ is at each occurrence H or C₁₋₁₀-alkyl, or two R⁵¹ groups, which can be from different W¹, W², W³ and W⁴ groups, together with the connecting atoms form a 5, 6 or 7 membered ring, which may be substituted with one to three C₁₋₆-alkyls,
   Z¹, Z² and Z³ are independently from each other selected from the group consisting of C₁₋₁₀-alkylene, C₅₋₇-cycloalkylene, C₆₋₁₄-arylene, 5 to 14 membered heteroarylene and polycyclic system containing at least one ring selected from C₆₋₁₄-aromatic ring and 5 to 14 membered heteroaromatic ring,
wherein
C₁₋₁₀-alkylene, C₅₋₇-cycloalkylene, C₆₋₁₄ membered arylene, 5 to 14 membered heteroarylene and polycyclic system containing at least one ring selected from C₆₋₁₄-aromatic ring and 5 to 14 membered heteroaromatic ring can be substituted with one to five C₁₋₂₀-alkyl or phenyl,
provided at least one of Z¹, Z² and Z³ is C₆₋₁₄-arylene, 5 to 14 membered heteroarylene or polycyclic system containing at least one ring selected from C₆₋₁₄-aromatic ring and 5 to 14 membered heteroaromatic ring.

Most preferably, L⁵⁰ is a linking group of formula

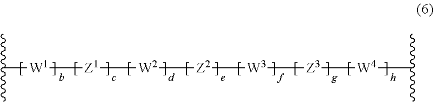

wherein
b, c, d, e, f, g and h are independently from each other 0 or 1, provided that at least one of c, e, and g is 1,
W¹, W², W³ and W⁴ are independently from each other selected from the group consisting of C(O), CR⁵¹═CR⁵¹ and ethynylene
wherein
R⁵¹ is H,
   Z¹, Z² and Z³ are independently from each other selected from the group consisting of C₁₋₁₀-alkylene, C₆₋₁₄-arylene, 5 to 14 membered heteroarylene, and polycyclic system containing at least one ring selected from C₆₋₁₄-aromatic ring and 5 to 14 membered heteroaromatic ring,
wherein
C₁₋₁₀-alkylene, C₆₋₁₄ membered arylene, 5 to 14 membered heteroarylene and polycyclic system containing at least one ring selected from C₆₋₁₄-aromatic ring and 5 to 14 membered heteroaromatic ring can be substituted with one or two C₁₋₂₀-alkyl or phenyl,
   provided at least one of Z¹, Z² and Z³ is C₆₋₁₄-arylene, 5 to 14 membered heteroarylene or polycyclic system containing at least one ring selected from C₆₋₁₄-aromatic ring and 5 to 14 membered heteroaromatic ring.

The preparation of crosslinking agents carrying at least two azide groups are described in various publications, for example WO 2015/004563, Cai, S. X.; Glenn, D. J.; Kanskar, M.; Wybourne, M. N.; Keana, J. F. W. Chem. Mater. 1994, 6, 1822-1829, Yan, M.; Cai, S. X.; Wybourne, M. N.; Keana, J. F. W. J. Mater. Chem. 1996, 6, 1249-1252, Touwslager, F. J.; Willard, N. P.; Leeuw, D. M. Applied Physics Letters 2002, 81, 4556, WO 04/100282, WO 2007/004995, WO 2009/068884, Png, R.-Q.; Chia, P.-J.; Tang, J.-C.; Liu, B.; Sivaramakrishnan S.; Zhou, M.; Khong, S.-H.; Chan, H. S. O.; Burroughes, J. H.; Chua, L.-L.; Friend, R. H.; Ho, P. K. H. Nature Materials 2010, 9(2), 152-152, and WO 2011/068482.

The composition of the present invention can be prepared by mixing the polymer of the present invention with the solvent, and optionally the crosslinking agent.

Also, part of the present invention is an electronic device comprising a layer i) comprising the polymers of the present invention or ii) formed from a composition of the present invention.

The electronic device can be a field-effect transistor, a capacitor, a light emitting diode, a photovoltaic device, a sensing device or a radio-frequency identification (RFID) tag.

Preferably, the electronic device is a field-effect transistor. Afield effect transistor can have various designs, for example a top-gate, bottom-contact field effect transistor or a bottom-gate, top-contact field effect transistor. The top-gate, bottom-contact field effect transistor comprises in the following order a substrate, source/drain electrodes, a semiconducting layer, a dielectric layer and a gate electrode. The bottom-gate, top-contact field effect transistor comprises in the following order a substrate, a gate electrode, a dielectric layer, a semiconducting layer and source/drain electrodes.

Preferably, the electronic device is a field-effect transistor and the layer i) comprising the polymers of the present invention or ii) formed from a composition of the present invention, is the dielectric layer.

The dielectric layer can have a thickness of 10 to 2000 nm, preferably of 50 to 1000 nm, more preferably of 100 to 800 nm, most preferably 400 to 600 nm.

Preferably, the semiconducting layer comprises an organic semiconducting material. Examples of organic semiconducting materials are polycyclic aromatic hydrocarbons consisting of linearly-fused aromatic rings such as anthracene, pentacene and derivatives thereof, polycyclic aromatic hydrocarbons consisting of two-dimensional fused aromatic rings such as perylene, perylene diimide derivatives, perylene dianhydride derivatives and naphthalene diimide derivatives, triphenylamine derivatives, oligomers and polymers containing aromatic units such as oligothiophene, oligophenylenevinylene, polythiophene, polythienylenevinylene polyparaphenylene, polypyrrole and polyaniline, hydrocarbon chains such as polyacetylenes, and diketopyrrolopyrrole-based materials.

For example, bis-alkinyl substituted polycyclic aromatic hydrocarbons consisting of linearly-fused aromatic rings are described in WO2007/068618.

For example, perylene diimide derivatives, perylene dianhydride derivatives and naphthalene diimide derivatives are described in WO2007/074137, WO2007/093643, WO2009/024512, WO2009/147237, WO2012/095790, WO2012/117089, WO2012/152598, WO2014/033622, WO2014/174435 and WO2015/193808.

For example, polymers comprising thiophene units are described in WO2010/000669, polymers comprising benzothiadiazol-cyclopentadithiophene units are described in WO2010/000755, polymers comprising dithienobenzathienothiophene units are described in WO2011/067192, polymers comprising dithienophthalimide units are described in WO2013/004730, polymers comprising thienothiophene-2,5-dione units as described in WO2012/146506, and polymers comprising Isoindigo-based units are described in WO2009/053291.

For example, diketopyrrolopyrrole-based materials and their synthesis are described in WO2005/049695, WO2008/000664, WO2010/049321, WO2010/049323, WO2010/108873, WO2010/136352, WO2010/136353, WO2012/041849, WO2012/175530, WO2013/083506, WO2013/083507 and WO2013/150005.

A summary on diketopyrrolopyrrole-based polymers suitable as semiconducting material in organic field effect transistors are also given in Christian B. Nielsen, Mathieu Turbiez and lain McCulloch, Advanced Materials 2013, 25, 1859 to 1880.

Preferably, the organic semiconducting material is at least one diketopyrrolopyrrole based material. More preferably, the organic semiconducting material is at least one diketopyrrolopyrrole based polymer. Even more preferably, the organic semiconducting material is at least one diketopyrrolopyrrole based polymer comprising units of formula

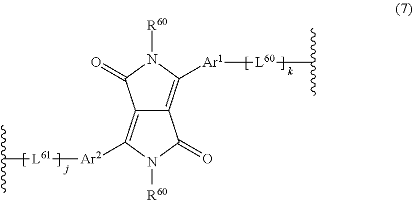

wherein
R⁶⁰ is at each occurrence C₁₋₃₀-alkyl, C₂₋₃₀-alkenyl or C₂₋₃₀-alkynyl, wherein C₁₋₃₀-alkyl, C₂₋₃₀-alkenyl and C₂₋₃₀-alkynyl can be substituted by one or more —Si(R¹⁰⁰)₃ or —OSi(R¹⁰⁰)₃, or one or more CH₂ groups of C₁₋₃₀-alkyl, C₂₋₃₀-alkenyl and C₂₋₃₀-alkynyl can be replaced by —Si(R¹⁰⁰)₂— or —[Si(R¹⁰⁰)₂—O]_{q}—Si(R¹⁰⁰)₂—, wherein R¹⁰⁰ is at each occurrence C₁₋₁₀-alkyl, and q is an integer from 1 to 20,
j and k are independently 0 or 1, and
Ar¹ and Ar² are independently arylene or heteroarylene, wherein arylene and heteroarylene can be substituted with one or more C₁₋₃₀-alkyl, C₂₋₃₀-alkenyl, C₂₋₃₀-alkynyl, O—C₁₋₃₀ alkyl, aryl or heteroaryl, which C₁₋₃₀-alkyl, C₂₋₃₀-alkenyl, C₂₋₃₀-alkynyl, O—C₁₋₃₀ alkyl, aryl and heteroaryl can be substituted with one or more C₁₋₂₀-alkyl, O—C₁₋₂₀-alkyl or phenyl,
L⁶⁰ and L⁶¹ are independently selected from the group consisting of

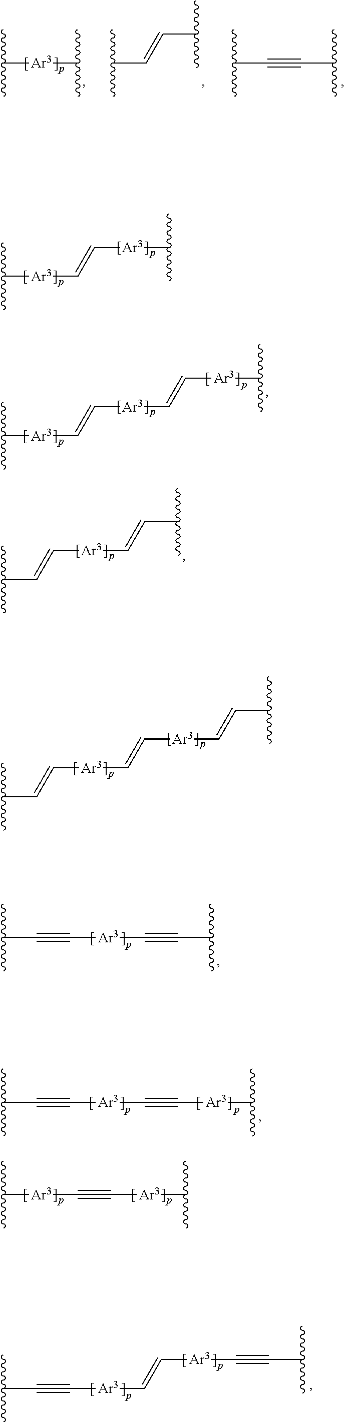

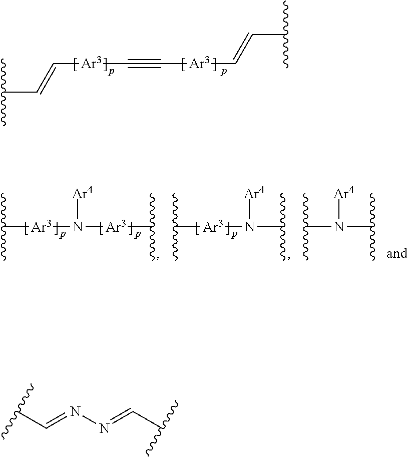

wherein
Ar³ is at each occurrence arylene or heteroarylene, wherein arylene and heteroarylene can be substituted with one or more C₁₋₃₀-alkyl, C₂₋₃₀-alkenyl, C₂₋₃₀-alkynyl, O—C₁₋₃₀-alkyl, aryl or heteroaryl, which C₁₋₃₀-alkyl, C₂₋₃₀-alkenyl, C₂₋₃₀-alkynyl, O—C₁₋₃₀-alkyl, aryl and heteroaryl can be substituted with one or more C₁₋₂₀-alkyl, O—C₁₋₂₀-alkyl or phenyl; and wherein adjacent Ar³ can be connected via a CR¹⁰¹R¹⁰¹, SiR¹⁰¹R¹⁰¹ or GeR¹⁰¹R¹⁰¹ linker, wherein R¹⁰¹ is at each occurrence H, C₁₋₃₀₋alkyl or aryl, which C₁₋₃₀-alkyl and aryl can be substituted with one or more C₁₋₂₀-alkyl, O—C₁₋₂₀-alkyl or phenyl,
p is at each occurrence an integer from 1 to 8, and
Ar⁴ is at each occurrence aryl or heteroaryl, wherein aryl and heteroaryl can be substituted with one or more C₁₋₃₀-alkyl, O—C₁₋₃₀ alkyl or phenyl, which phenyl can be substituted with C₁₋₂₀-alkyl or O—C₁₋₂₀-alkyl.

C₂₋₃₀-alkenyl can be branched or unbranched. Examples of C₂₋₃₀-alkenyl are vinyl, propenyl, cis-2-butenyl, trans-2-butenyl, 3-butenyl, cis-2-pentenyl, trans-2-pentenyl, cis-3-pentenyl, trans-3-pentenyl, 4-pentenyl, 2-methyl-3-butenyl, hexenyl, heptenyl, octenyl, nonenyl, docenyl, linoleyl (C₁₈), linolenyl (C₁₈), oleyl (C₁₈), and arachidonyl (C₂₀), and erucyl (C₂₂).

C₂₋₃₀-alkynyl can be branched or unbranched. Examples of C₂₋₃₀-alkynyl are ethynyl, 2-propynyl, 2-butynyl, 3-butynyl, pentynyl, hexynyl, heptynyl, octynyl, nonynyl, decynyl, undecynyl, dodecynyl, undecynyl, dodecynyl, tridecynyl, tetradecynyl, pentadecynyl, hexadecynyl, heptadecynyl, octadecynyl, nonadecynyl and icosynyl (C₂₀).

Arylene is a bivalent aromatic ring system, consisting of one aromatic ring or of two to eight condensed aromatic rings, wherein all rings are formed from carbon atoms. Preferably, arylene is a bivalent aromatic ring system consisting of one aromatic ring or of two to four condensed aromatic rings, wherein all rings are formed from carbon atoms.

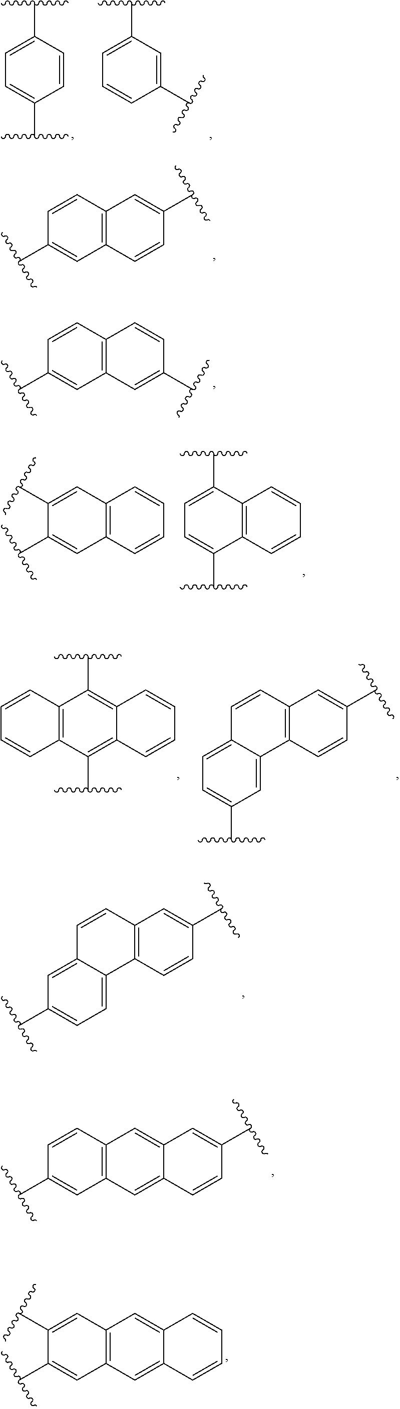

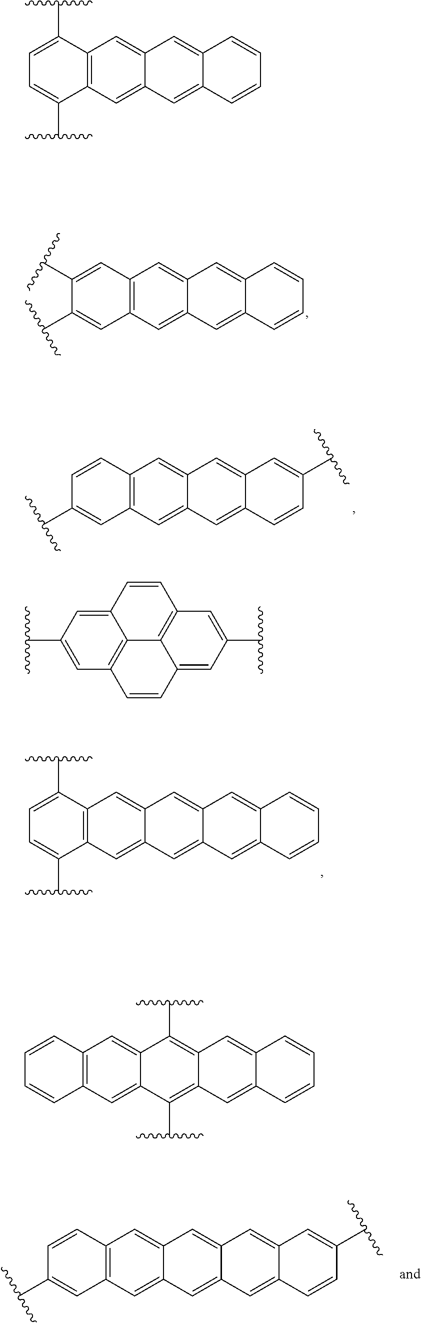

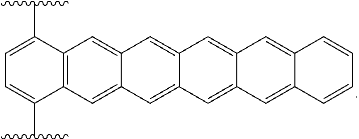 [SMILES: *c1ccc(*)c2cc3cc4cc5cc6ccccc6cc5cc4cc3cc12]

Heteroarylene is a bivalent aromatic ring system consisting of one aromatic ring or of two to eight condensed aromatic rings, wherein at least one aromatic ring contains at least one heteroatom selected from the group consisting of S, O, N and Se. Preferably, heteroarylene is a bivalent aromatic ring system consisting of one aromatic ring or of two to four condensed aromatic rings, wherein at least one aromatic ring contains at least one heteroatom selected from the group consisting of S, O, N and Se.

Examples of heteroarylene are

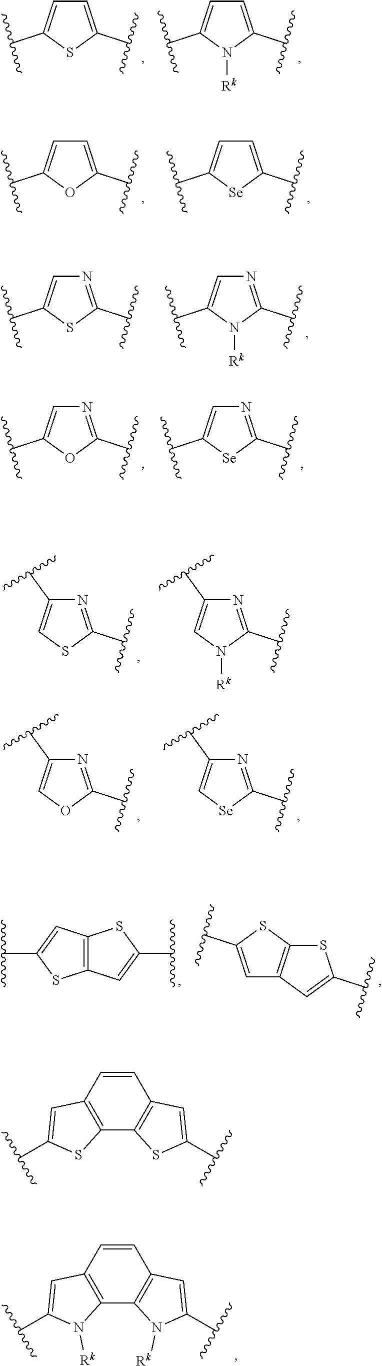

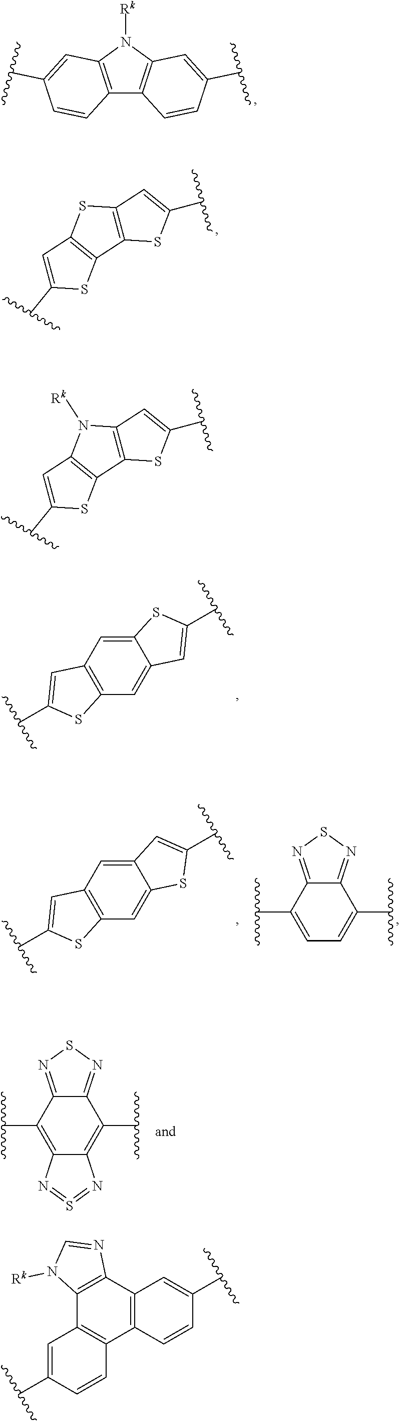

wherein R^{k} is H, C₁₋₂₀-alkyl, aryl or heteroaryl, which C₁₋₂₀-alkyl, aryl and heteroaryl can be substituted with one or more C₁₋₆-alkyl, O—C₁₋₆-alkyl or phenyl.

Examples of adjacent Ar³, which are connected via a CR¹⁰⁰R¹⁰⁰, SiR¹⁰⁰R¹⁰⁰ or GeR¹⁰⁰R¹⁰⁰ linker, wherein R¹⁰⁰ is at each occurrence H, C₁₋₃₀-alkyl or aryl, which C₁₋₃₀-alkyl and aryl can be substituted with one or more C₁₋₂₀-alkyl, O—C₁₋₂₀-alkyl or phenyl, and p is at each occurrence an integer from 1 to 8, are

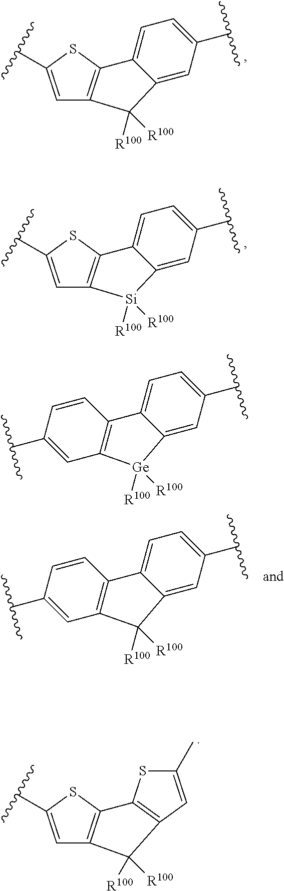

Aryl is a monovalent aromatic ring system, consisting of one aromatic ring or of two to eight condensed aromatic rings, wherein all rings are formed from carbon atoms. Preferably, aryl is a monovalent aromatic ring system consisting of one aromatic ring or of two to four condensed aromatic rings, wherein all rings are formed from carbon atoms.

Examples of aryl are

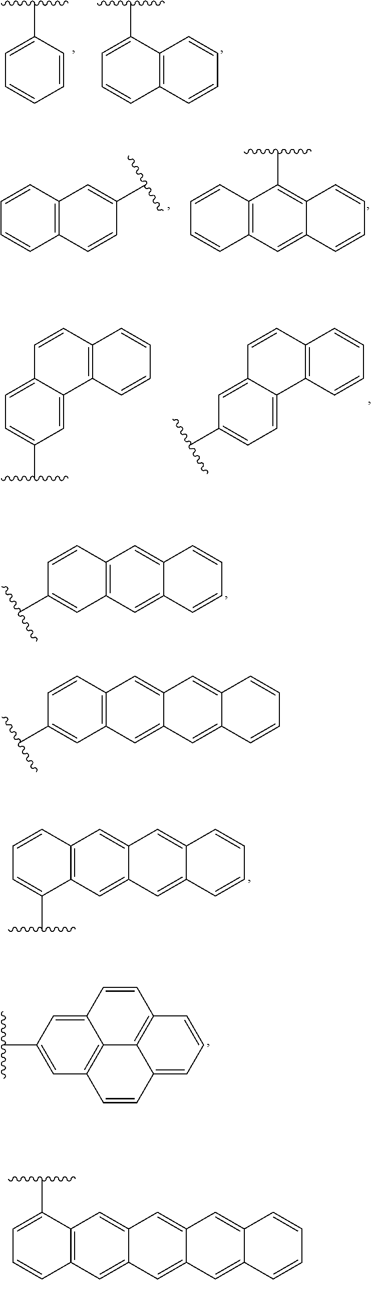

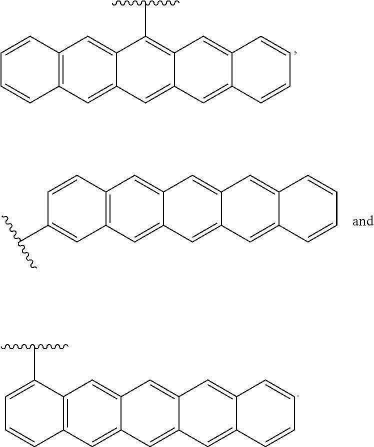 [SMILES: *c1c2cc3ccccc3cc2cc2cc3ccccc3cc12 ; *c1ccc2cc3cc4cc5ccccc5cc4cc3cc2c1 ; *c1cccc2cc3cc4cc5ccccc5cc4cc3cc12]

Heteroaryl is a monovalent aromatic ring system consisting of one aromatic ring or of two to eight condensed aromatic rings, wherein at least one aromatic ring contains at least one heteroatom selected from the group consisting of S, O, N and Se. Preferably, heteroaryl is a monovalent aromatic ring system consisting of one aromatic ring or of two to four condensed aromatic rings, wherein at least one aromatic ring contains at least one heteroatom selected from the group consisting of S, O, N and Se.

Examples of heteroaryl are

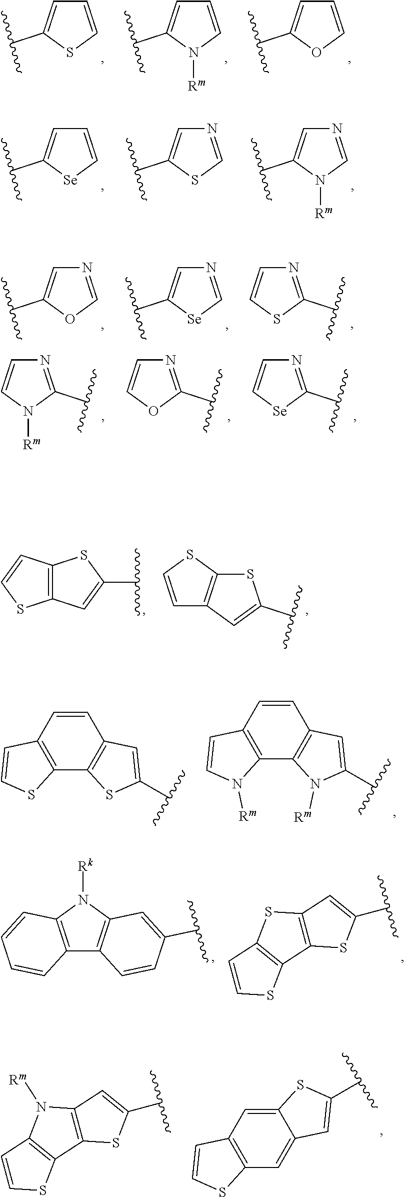

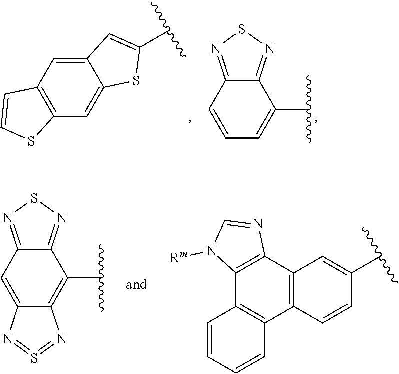

wherein R^{m} is H, C₁₋₂₀-alkyl, aryl or heteroaryl, which C₁₋₂₀-alkyl, aryl and heteroaryl can be substituted with one or more C₁₋₆-alkyl, O—C₁₋₆-alkyl or phenyl.

Examples of L⁶⁰ and L⁶¹ are

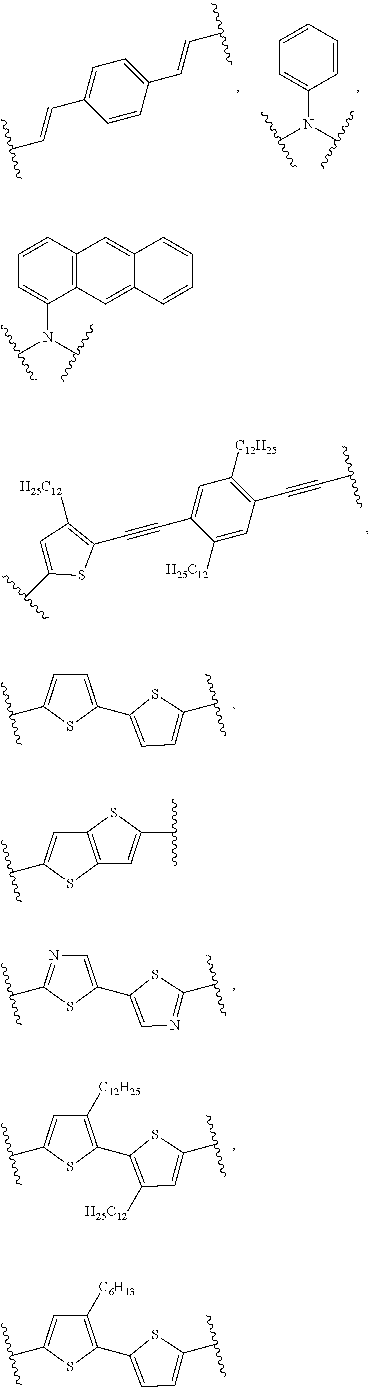

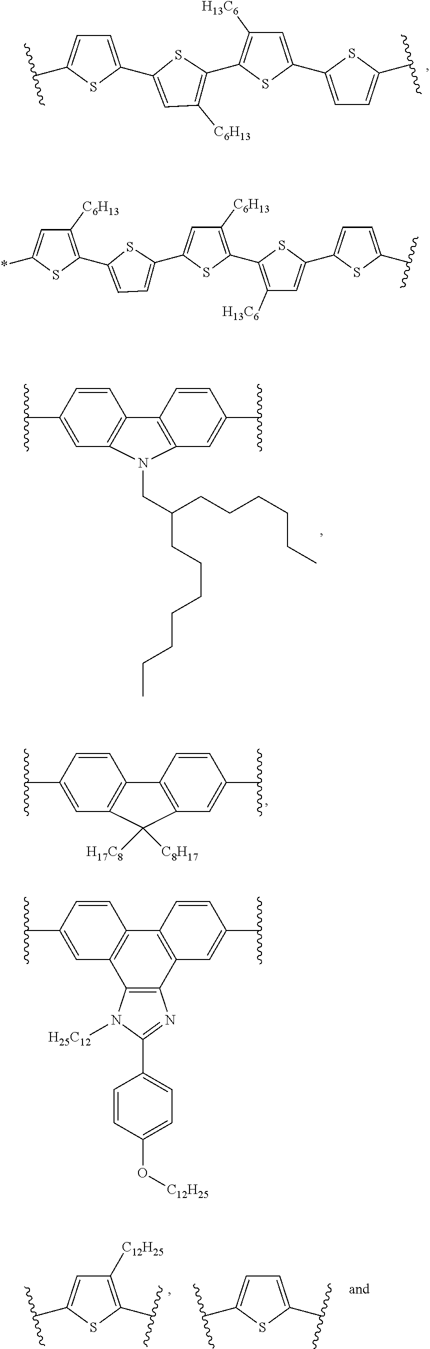

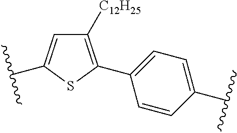

The diketopyrrolopyrrole-based polymers comprising units of formula (7) can comprise other repeating units. The diketopyrrolopyrrole-based polymers comprising units of formula (7) can be homopolymers or copolymers. The copolymers can be random or block.

Preferably, the diketopyrrolopyrrole-based polymers comprising units of formula (7) comprise at least 50% by weight of units of formula (7) based on the weight of the polymer, more preferably at least 70%, even more preferably at least 90% by weight of units of formula (7) based on the weight of the polymer. Most preferably, diketopyrrolopyrrole-based polymers essentially consist of units of formula (7). The diketopyrrolopyrrole-based polymers essentially consisting of units of formula (7) can be homopolymers or copolymers.

More preferably, the diketopyrrolopyrrole-based polymers comprising units of formula (7) essential y consist of units of formula

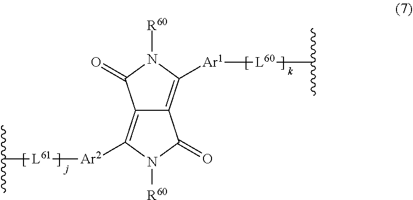

wherein
R⁶⁰ is C₆₋₃₀-alkyl,
j and k are independently 0 or 1, provided n and m are not both 0, and
Ar¹ and Ar² are independently

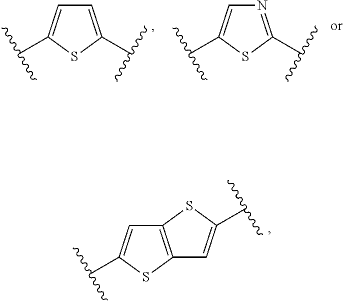 [SMILES: *c1ccc(*)s1 ; *c1cnc(*)s1 ; *c1cc2sc(*)cc2s1]

L⁶⁰ and L⁶¹ are independently selected from the group consisting of

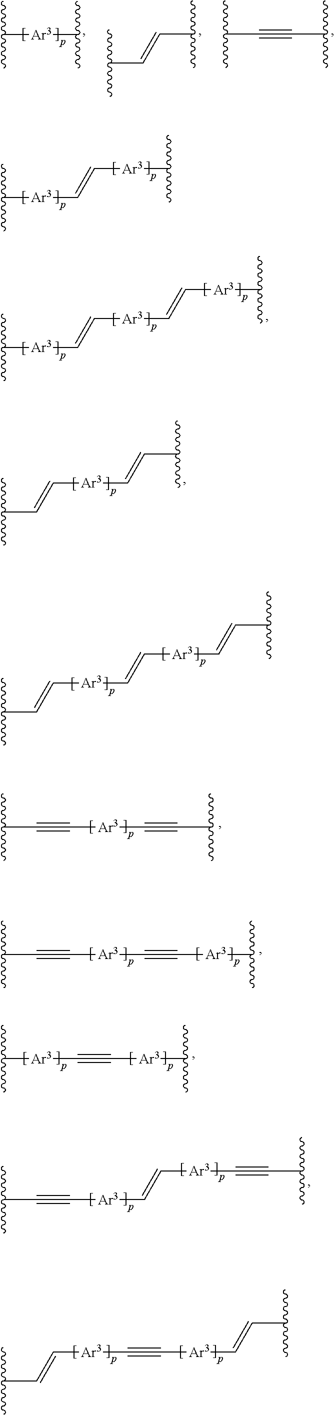

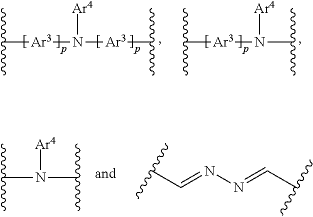

wherein
Ar³ is at each occurrence arylene or heteroarylene, wherein arylene and heteroarylene can be substituted with one or more C₁₋₃₀-alkyl, C₂₋₃₀-alkenyl, C₂₋₃₀-alkynyl, O—C₁₋₃₀-alkyl, aryl or heteroaryl, which C₁₋₃₀-alkyl, C₂₋₃₀-alkenyl, C₂₋₃₀-alkynyl, O—C₁₋₃₀-alkyl, aryl and heteroaryl can be substituted with one or more C₁₋₂₀-alkyl, O—C₁₋₂₀-alkyl or phenyl; and wherein adjacent Ar³ can be connected via a CR¹⁰¹R¹⁰¹, SiR¹⁰¹R¹⁰¹ or GeR¹⁰¹R¹⁰¹ linker, wherein R¹⁰¹ is at each occurrence H, C₁₋₃₀-alkyl or aryl, which C₁₋₃₀-alkyl and aryl can be substituted with one or more C₁₋₂₀-alkyl, O—C₁₋₂₀-alkyl or phenyl,
p is at each occurrence an integer from 1 to 8, and
Ar⁴ is at each occurrence aryl or heteroaryl, wherein aryl and heteroaryl can be substituted with one or more C₁₋₃₀-alkyl, O—C₁₋₃₀-alkyl or phenyl, which phenyl can be substituted with C₁₋₂₀-alkyl or O—C₁₋₂₀-alkyl.

The substrate for the top-gate, bottom-contact organic field effect transistor can be any suitable substrate such as glass, or a plastic substrate such as silicon, polyethersulfone, polycarbonate, polysulfone, polyethylene terephthalate (PET) and polyethylene naphthalate (PEN).

The source and drain electrodes can be made from any suitable material. Examples of suitable materials are gold (Au), silver (Ag), chromium (Cr) or copper (Cu), as well as alloys comprising at least one of these metals. The source and drain electrodes can have a thickness of 1 to 100 nm, preferably from 20 to 70 nm.

The gate electrode can be made from any suitable gate material such as aluminium (Al), tungsten (W), indium tin oxide or gold (Au), or alloys comprising at least one of these metals, or highly doped silicon (Si). The gate electrode can have a thickness of 1 to 200 nm, preferably from 5 to 100 nm.

The channel length (L) of the organic field effect transistor, which is the distance between source and drain electrode, is typically in the range of 3 to 2000 μm, preferably 3 to 20 μm. The ration width (W)/length (L) of the organic field effect transistor is usually between 3/1 to 10/1.

The field effect transistor can comprise additional layers such as further semiconducting or dielectric layers, or self-assembled monolayers (SAMs).

Also, part of the present invention is a process for the preparation of a field effect transistor comprising the steps of applying the composition of the present invention on a precursor of the field effect transistor, and removing the solvent of the composition of the present invention and forming the dielectric layer.

The precursor can be any precursor such as a precursor comprising in the following order a substrate, source/drain electrodes and a semiconducting layer, or a precursor comprising in the following order a substrate, and a gate electrode.

The composition of the present invention can be applied by techniques known in the art. Preferably, the composition of the present invention is applied by liquid processing techniques such as spin coating, blading, slot-die coating, drop-casting, spray-coating, ink-jetting or soaking of the substrate of the electronic device in the composition. Preferably, the composition of the present invention is applied by spin-coating. After applying the composition of the present invention, the solvent is removed by techniques known in the art, for example by heat treatment at a temperature from 40 to 120° C., preferably at a temperature of from 70 to 100° C. If the composition of the present invention also comprises a photo-crosslinkable crosslinking agent, an additional light treatment step can be performed. Preferably, the light treatment is UV light treatment and more preferably UV light treatment at a wavelength of 365 nm.

The semiconducting material can be applied by techniques known in the art. Preferably, a composition comprising the organic semiconducting layer is applied by liquid processing techniques such as spin coating, blading, slot-die coating, drop-casting, spray-coating, ink-jetting or soaking of the substrate of the electronic device in the composition. Preferably, the composition comprising the organic semiconducting layer is applied by spin-coating. The semiconducting layer can be treated with heat at a temperature from 40 to 120° C., preferably at a temperature from 70 to 100° C.

The source/drain electrodes and the gate electrode can be applied by techniques known in the art, for example by evaporation using a mask. The gate electrode can be made from any suitable gate material such as highly doped silicon, aluminium (Al), tungsten (W), indium tin oxide or gold (Au), or alloys comprising at least one of these metals.

Also, part of the present invention is the use of the polymers of the present invention as dielectric material.

The polymers of the present invention are advantageous in that the polymers are suitable as dielectric materials for field effect transistors that show high drain currents at low gate-source voltages and thus can be operated at low gate-source voltages. The polymers of the present invention are also advantageous in that the polymers are compatible with liquid processing techniques such as spin coating. In addition, the polymers of the present invention, when used as dielectric material in a field effect transistor, yield field effect transistors showing high charge carrier mobility. Furthermore, the polymers of the present invention can be prepared in high yields in economic processes requiring reaction times of less than 8 hours.

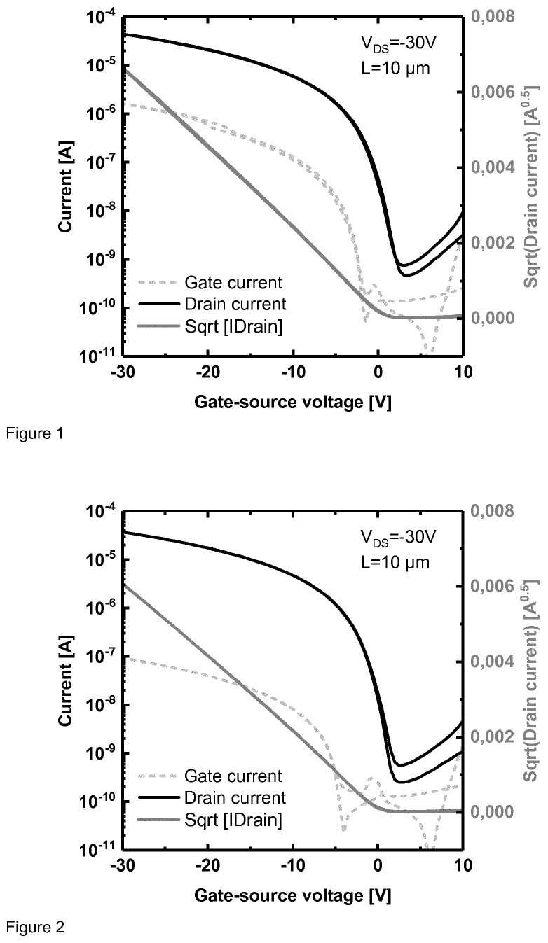

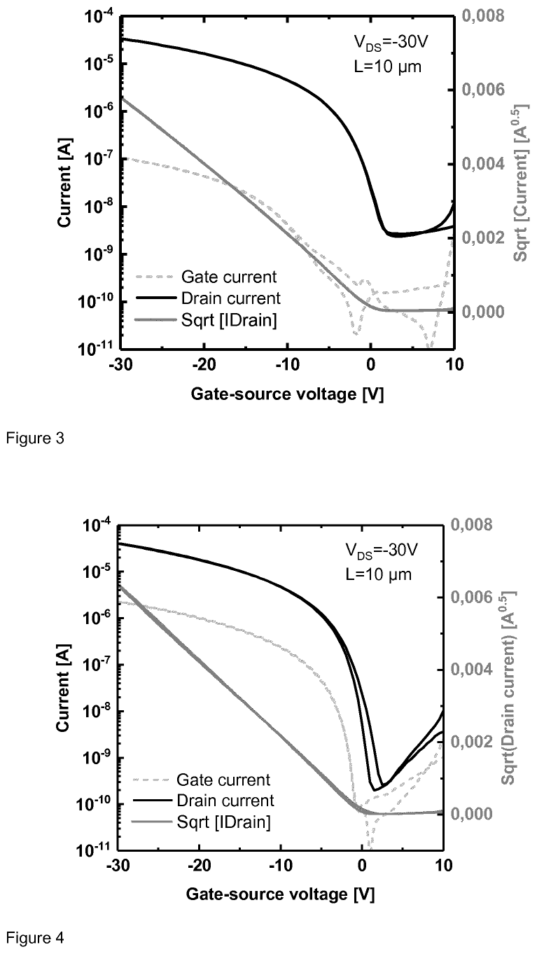

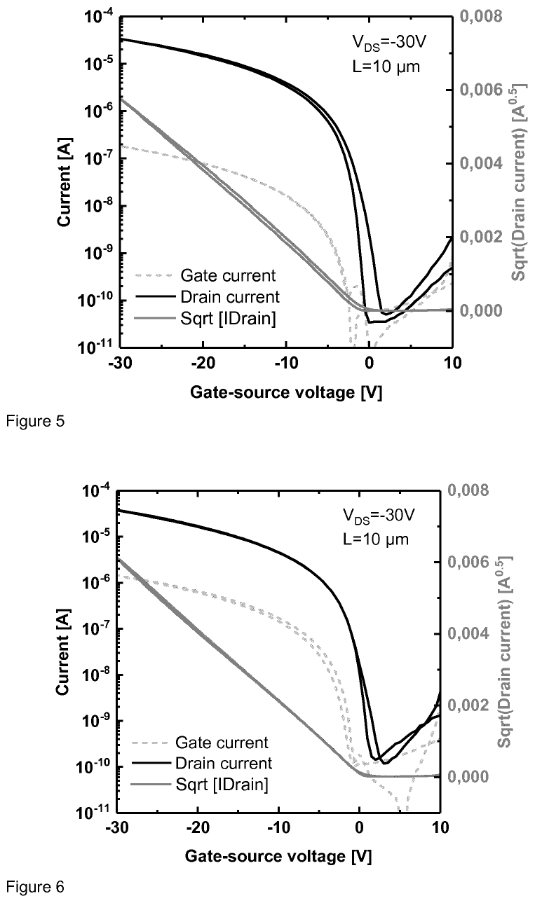

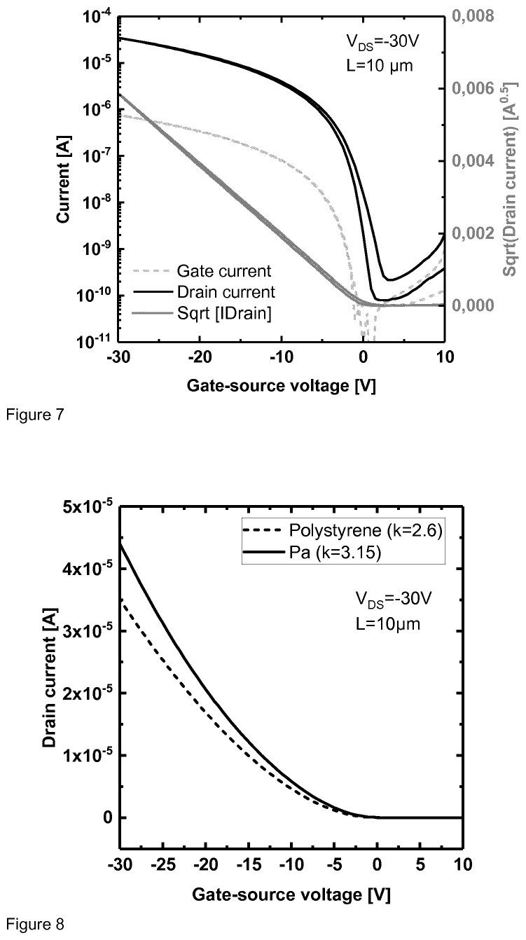

FIGS. 1 to 7 show the drain current I_{d} in relation to the gate-source voltage V_{gs} (transfer curve) for the top-gate, bottom-contact (TGBC) field effect transistor of example 4 comprising Pa (FIG. 1), Pb (FIG. 2), Pc (FIG. 3), Pd (FIG. 4), Pe (FIG. 5), Pf (FIG. 6) and Pg (FIG. 7), respectively, as dielectric material at a drain-source voltage V_{ds} of −30V. The solid black line curve shows the drain current plotted on a logarithmic scale (left y-axis). The solid dark grey line shows the square root of drain current plotted on a linear scale (right y-axis). In addition, FIGS. 1 to 7 show the gate current plotted on a logarithmic scale (left y-axis) as light-grey, dotted line.

FIG. 8 shows the drain current plotted on a linear scale (left y-axis) for the top-gate, bottom-contact (TGBC) field effect transistor of example 4 comprising Pa, and for the top-gate, bottom-contact (TGBC) field effect transistor of comparative example 1 comprising polystyrene.

### EXAMPLES

### Example 1a

### Preparation of Polymer Pa

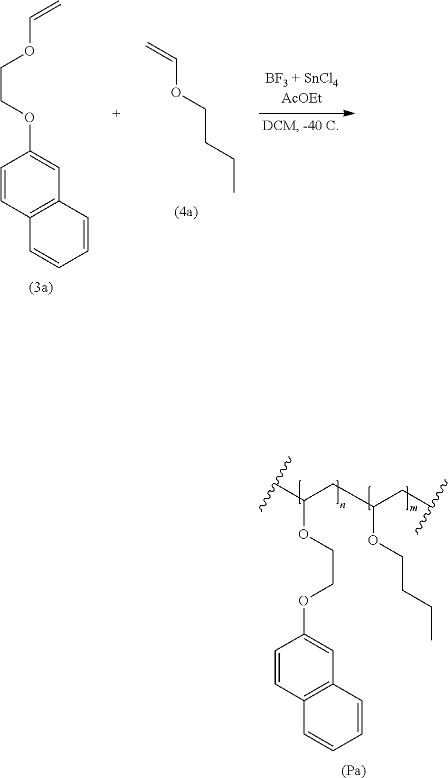

In a three-neck bottom flask, compound 3a, prepared as describes in example 2a, (2 g, 9.3 mmol) and vinylbutyl ether (4a) (0.23 g 2.3 mmol) were dissolved in dichloromethane (10 mL) together with catalytic amount of ethyl acetate (0.1 mL). The solution was then cooled to −40° C. by means of an acetonitrile/dry ice bath. To the cooled solution, SnCl₄ (0.5% mol) and BF₃ in 1M DCM solution (0.5% mol) were subsequently added, keeping the temperature at −40° C. After stirring for 5 to 6 hrs, polymer Pa was precipitated in ⁱPrOH. The obtained white solid was filtered, dried and precipitated two more times in ⁱPrOH by dissolving it in the minimal amount of toluene. Polymer Pa was obtained in quantitative yield as white solid that was then characterized by gel permeation chromatography and H¹-NMR. δ ppm, CCl₂D₂: 7.7-6.8 (m, broad); 4.2-3.5 (m, broad); 3.5-3.2 (m, broad); 2.0-1.2 (m, broad); 0.7-0.95 (m, broad). Mn=312000 g/mol, Mz=837000 g/mol. PDI=2.7.

### Example 1b

### Preparation of Polymer Pb

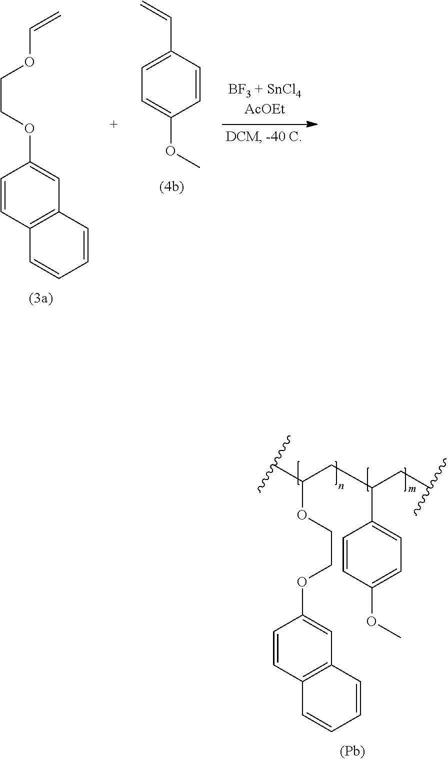

In a three-neck bottom flask, compound 3a, prepared as described in example 2a, (2.0 g, 9 mmol) and methoxystyrene (4b) (0.42 g, 3 mmol) were dissolved in dichloromethane (10 mL) together with catalytic amount of ethyl acetate (0.1 mL). The solution was then cooled to −40° C. by means of an acetonitrile/dry ice bath. To the cooled solution, SnCl₄ (0.5% mol) and BF₃ in 1M DCM solution (0.5% mol) were subsequently added, keeping the temperature at −40° C. After stirring for 6 hrs, polymer Pb was precipitated in ⁱPrOH. The obtained white solid was filtered, dried and precipitated two more times in ⁱPrOH by dissolving it in the minimal amount of toluene. Polymer Pb was obtained in 95% yield as white solid that was then characterized by gel permeation chromatography and H¹-NMR (δ ppm, CCl₂D₂: 7.8-6.3 (m, broad); 4.1-3.5 (m, broad); 2.0-1.2 (m, broad). Mn=29000 g/mol, Mz=98000 g/mol. PDI=2.0.

### Example 1c

### Preparation of Polymer Pc

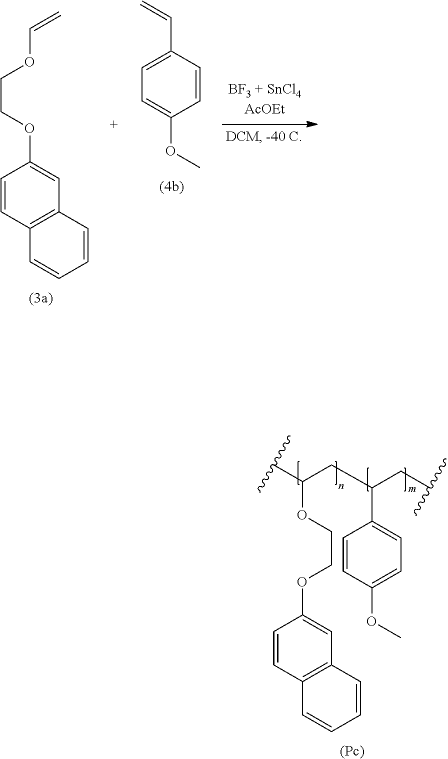

In a three-neck bottom flask, compound 3a, prepared as described in example 2a, (1.5 g, 7 mmol) and methoxystyrene (4b) (0.94 g 7 mmol) were dissolved in dichloromethane (10 mL) together with catalytic amount of ethyl acetate (0.1 mL). The solution was then cooled to −40° C. by means of an acetonitrile/dry ice bath. To the cooled solution, SnCl₄ (0.5% mol) and BF₃ in 1M DCM solution (0.5% mol) were subsequently added, keeping the temperature at −40° C. After stirring for 6 hrs, polymer Pc was precipitated in ⁱPrOH. The obtained white solid was filtered, dried and precipitated two more times in ⁱPrOH by dissolving it in the minimal amount of toluene. Polymer Pc was obtained in 95% yield as white solid that was then characterized by gel permeation chromatography and H¹-NMR. ¹H-NMR δ ppm, CCl₂D₂: 7.8-6.3 (m, broad); 4.1-3.8 (m, broad); 3.8-3.5 (m, broad); 2.0-1.2 (m, broad). Mn=43000 g/mol, Mz=117000 g/mol. PDI=1.7

### Example 1d

### Preparation of Dielectric Polymer Pd

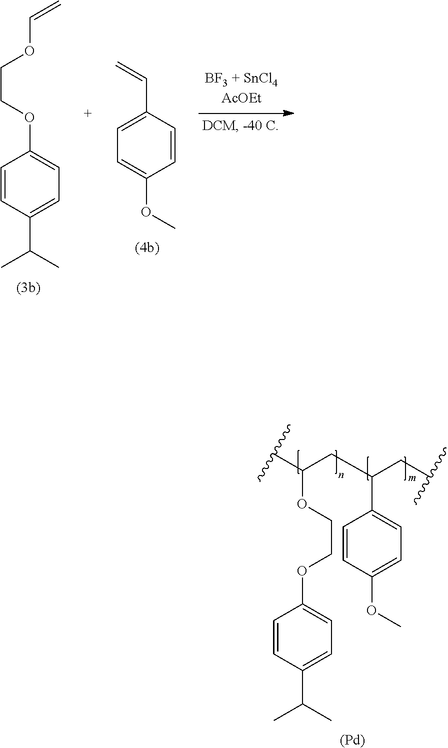

In a three-neck bottom flask, compound 3b, prepared as described in example 2b, (1.0 g, 5 mmol) and methoxystyrene (4b) (1.34 g 5 mmol) were dissolved in dichloromethane (10 mL) together with catalytic amount of ethyl acetate (0.1 mL). The solution was then cooled to −40° C. by means of an acetonitrile/dry ice bath. To the cooled solution, SnCl₄ (0.5% mol) and BF₃ in 1M DCM solution (0.5% mol) were subsequently added, keeping the temperature at −40° C. After stirring for 6 hrs, polymer Pd was precipitated in ⁱPrOH. The obtained white solid was filtered, dried and precipitated two more times in ⁱPrOH by dissolving it in the minimal amount of toluene. Polymer Pd was obtained in 67% yield as white solid that was then characterized by gel permeation chromatography and H¹-NMR. ¹H-NMR δ ppm, CCl₂D₂: 7.1-6.9 (m, broad); 6.8-6.3 (m, broad); 4.0-3.5 (m, broad); 2.7-2.8 (m, broad); 2.0-1.2 (m, broad); 1.2-1.1 (m, broad). Mn=14000 g/mol, Mz=44000 g/mol. PDI=1.9.

### Example 1e

### Preparation of Polymer Pe

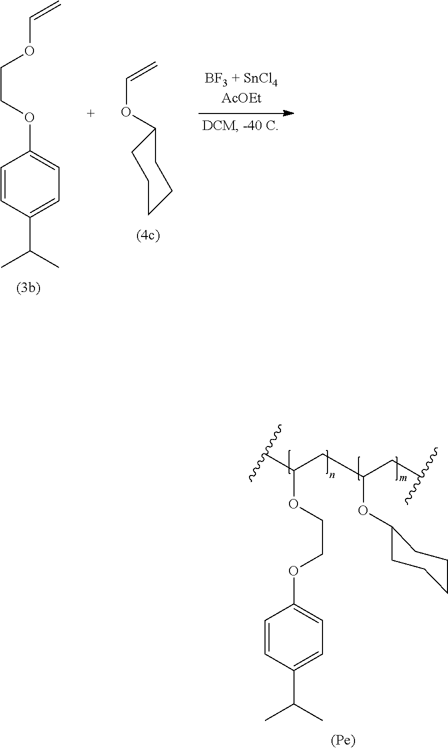

In a three-neck bottom flask, compound 3b, prepared as described in example 2b, (1.03 g, 0.5 mmol) and cyclohexylvinylether (4c) (0.65 g 10 mmol) were dissolved in dichloromethane (10 mL) together with catalytic amount of ethyl acetate (0.1 mL). The solution was then cooled to −40° C. by means of an acetonitrile/dry ice bath. To the cooled solution, SnCl₄ (0.5% mol) and BF₃ in 1M DCM solution (0.5% mol) were subsequently added, keeping the temperature at −40° C. After stirring for 6 hrs, polymer Pe was precipitated in ⁱPrOH. The obtained white solid was filtered, dried and precipitated two more times in ⁱPrOH by dissolving it in the minimal amount of toluene. Polymer Pe was obtained in quantitative yield as white solid that was then characterized by gel permeation chromatography and H¹-NMR. ¹H-NMR δ ppm, CCl₂D₂: 7.1-6.9 (m, broad); 6.8-6.6 (m, broad); 4.0-3.4 (m, broad); 3.3-3.2 (m, broad); 2.8-2.7 (m, broad); 1.9-1.3 (m, broad); 1.3-1.1 (m, broad). Mn=25000 g/mol, Mz=125000 g/mol. PDI=2.4.

### Example 1f

### Preparation of Polymer Pf

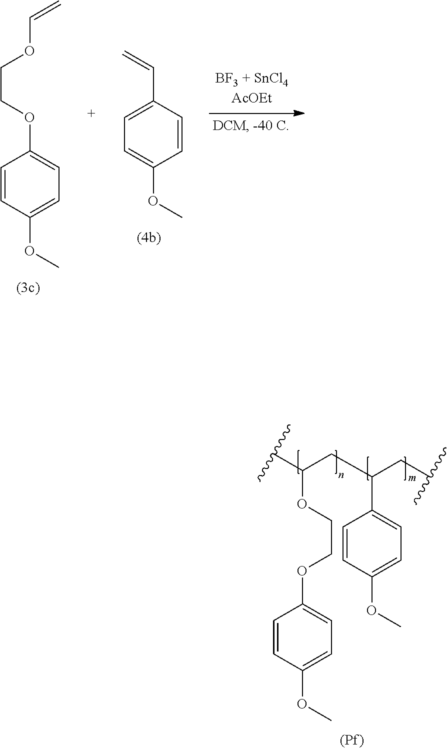

In a three-neck bottom flask, compound 3c, prepared as described in example 2c, (1.0 g, 5 mmol) and methoxystyrene (4b)(1.34 g 5 mmol) were dissolved in dichloromethane (10 mL) together with catalytic amount of ethyl acetate (0.1 mL). The solution was then cooled to −40° C. by the means of an acetonitrile/dry ice bath. To the cooled solution, SnCl₄ (0.5% mol) and BF₃ in 1M DCM solution (0.5% mol) were subsequently added, keeping the temperature at −40° C. After stirring for 6 hrs, polymer Pf was precipitated in ⁱPrOH. The obtained white solid was filtered, dried and precipitated two more times in ⁱPrOH by dissolving it in the minimal amount of toluene. Polymer Pf was obtained in quantitative yield as white solid that was then characterized by gel permeation chromatography and H¹-NMR. ¹H-NMR δ ppm, CCl₂D₂: 6.8-6.6 (m, broad); 3.9-3.6 (m, broad); 1.9-1.6 (m, broad). Mn=28000 g/mol, Mz=98000 g/mol, PDI=1.9.

### Example 1g

### Preparation of Polymer Pg

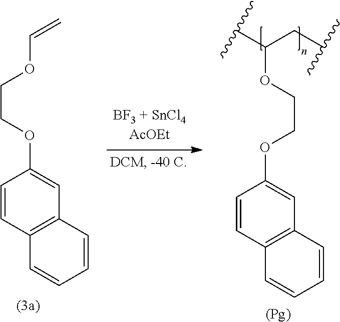

In a three-neck bottom flask, compound 3a, (12.0 g, 56 mmol), prepared as described in example 2a, was dissolved in dry dichloromethane (50 mL) together with catalytic amount of ethyl acetate (0.1 mL). The solution was then cooled to −40° C. by the means of an acetonitrile/dry ice bath. To the cooled solution, SnCl₄ (0.56 mol) and BF₃ in 1M DCM solution (0.56 mol) were subsequently added, keeping the temperature at −40° C. After stirring for 6 hrs, polymer Pg was precipitated in ⁱPrOH (250 mL). The obtained white solid was filtered, dried and precipitated two more times in ⁱPrOH by dissolving it in the minimal amount of toluene. The polymer was obtained in 88% yield (10.6 g) as pale gray solid that was then characterized by gel permeation chromatography and 1H-NMR. Mn=50K, Mz=622 k, PDI=3.5 ¹H-NMR (δ ppm, CCl₂D₂: 77-7.3 (m, broad); 6.9-67 (m, broad); 4.1-3.6 (m, broad); 2.0-1.6 (m, broad).

### Example 2a

### Preparation of Compound 3a

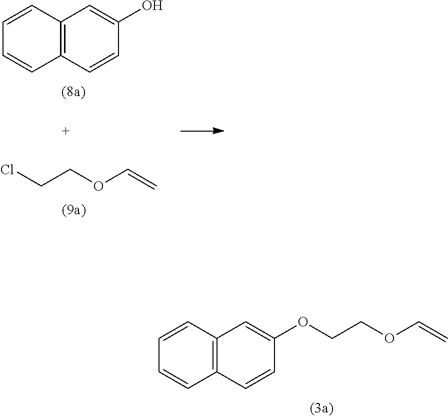

Compound 8a (0.2 mol) was dissolved in dimethyl formamide (100 mL) together with K₂CO₃ (57.5 g, 0.4 mol) and compound 9a (27.1 g, 0.25 mol). The reaction mixture was heated at 80° C. overnight. Water was added to the cooled solution until the precipitation of the solid monomer was induced or a phase separation of the liquid from water was performed. Yield: 92% Recrystallization from cyclohexane yielded a pale gay powder. ¹H-NMR δ ppm, CCl₂D₂: 7.77-7.72 (m, 3H), 7.43 (td, 1H, δ₁=7 Hz, δ₂=1 Hz), 7.33 (td, 1H, δ₁=7 Hz, δ₂=1 Hz), 7.17-7.14 (m, 2H), 6.55 (dd, 1H, δ₁=MHz, δ₂=7 Hz), 4.09-4.06 (m, 2H), 4.24 (d, 1H, δ₁=2 Hz), 4.33-4.27 (m, 3H).

### Example 2b

### Preparation of Compound 3b

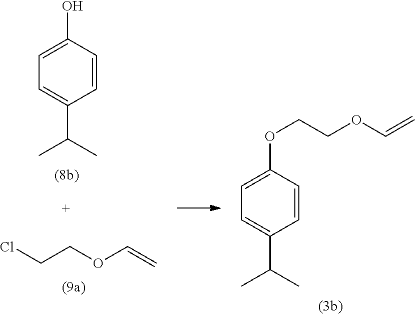

Compound 8b (0.2 mol) was dissolved in dimethyl formamide (100 mL) together with K₂CO₃ (57.5 g, 0.4 mol) and compound 9a (27.1 g, 0.25 mol). The reaction mixture was heated at 80° C. overnight. Water was added to the cooled solution until the precipitation of the solid monomer was induced or a phase separation of the liquid from water was performed. Yield: 89%. The crude was distilled (2.2 10⁻¹ mbar, T=110° C.) yielding a colorless oil. ¹H-NMR δ ppm, CCl₂D₂: 7.13 (d, 2H, δ₁=8 Hz), 6.83 (d, 2H, δ₁=8 Hz), 6.52 (dd, 1H, δ₁=MHz, δ₂=7 Hz), 4.23 (dd, 1H, δ₁=MHz, δ₂=2 Hz), 4.15-4.13 (m, 2H), 4.07 (dd, 1H, δ₁=7 Hz, δ₂=2 Hz), 4.00-3.98 (m, 2H), 2.84 (seq, 1H, δ₁=4 Hz), 1.20 (d, 6H, δ₁=4 Hz).

### Example 2c

### Preparation of Compound 3c

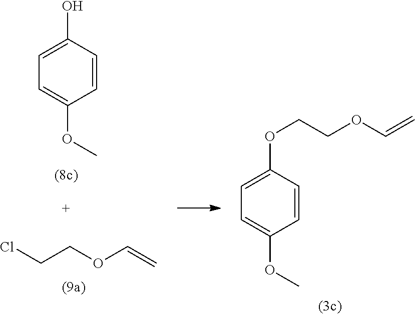

Compound 8c (0.2 mol) was dissolved in dimethyl formamide (100 mL) together with K₂CO₃ (57.5 g, 0.4 mol) and compound 9a (27.1 g, 0.25 mol). The reaction mixture was heated at 80° C. overnight. Water was added to the cooled solution until the precipitation of the solid monomer was induced or a phase separation of the liquid from water was performed. Yield: 90%. The crude was used without any further purification. ¹H-NMR δ ppm, CCl₂D₂: 6.85-6.80 (m, 4H), 6.53 (dd, 1H, δ₁=14 Hz, δ₂=6 Hz), 4.23 (d, 1H, δ₁=MHz), 4.13-4.11 (m, 2H), 4.04 (d, 1H, δ₁=6 Hz), 3.99-3.98 (m, 2H), 3.73 (s, 3H).

### Example 3

### Preparation of Capacitors Comprising Polymers Pa, Pb, Pc, Pd, Pe, Pf and Pg, Respectively

Compositions comprising polymer Pa, Pb, Pc, Pd, Pe, Pf and Pg, respectively, and a solvent as listed in table 1 were filtered with a 0.7 μm filter. The composition comprising polymer Pa was applied on a glass substrate covered with a conductive indium tin oxide (ITO) layer by spin coating under the conditions mentioned in table 1. The compositions comprising polymer Pb, Pc, Pd, Pe, Pf and Pg, respectively, were applied on a PET substrate with lithographically patterned gold electrodes by spin-coating under the conditions mentioned in table 1. The wet films obtained were baked at 90° C. for 30 minutes on a hot plate to obtain polymer layers with a thickness as indicated in table 1. Gold top-electrodes (area see table 1) were then vacuum-deposited through a shadow mask on the polymer layers at a pressure of below 1×10⁻⁵ mbar.

TABLE 1

| | | | Spin coating | | | |
|---|---|---|---|---|---|---|
| Composition | | | Spin- | | Layer | |
| | Polymer | | speed | Spin | thickness | Area |
| Polymer | [wt %]^{a} | Solvent | [rpm] | time [s] | [nm] | [mm²] |
| Pa | 10 | butyl acetate | 1500 | 30 | 489 | 2.9 |
| Pb | 10 | butyl acetate | 1500 | 30 | 560 | 1.4 |
| Pc | 12 | butyl acetate | 1500 | 30 | 450 | 1.4 |
| Pd | 8 | butyl acetate | 1200 | 30 | 319 | 1.4 |
| Pe | 8 | butyl acetate | 1500 | 30 | 407 | 1.4 |
| Pf | 10 | butyl acetate | 1500 | 30 | 473 | 1.4 |
| Pg | 12 | PGMEA/CP^{b} | 1500 | 30 | 357 | 1.4 |
| | | 9/1 | | | | |

^{a}based on the weight of the composition.
^{b}Propylene glycol methyl ether acetate/cyclopentanone.

The capacitors obtained were characterized by measuring the complex capacitance with a LCR meter Agilent 4284A (signal amplitude 1 V) to obtain the relative permittivity K=K′+iK″, where the K′ is the dielectric constant and K″ is a measure of the dielectric loss.

K′ is calculated by the following equation:

K′=C×d/(A×epsilon₀)

with C is the capacitance measured by the LCR meter, d the thickness of the dielectric layer, A the area of the capacitor and epsilon₀ is the vacuum permittivity (8,85E-12 F/m).

K″ is calculated by:

K″=tan(delta)×K′

with tan (delta) measured by the LCR meter.

TABLE 2

| | K′ | K′ | K″ | K″ |
|---|---|---|---|---|
| Polymer | (20 Hz) | (100 kHz) | (20 Hz) | (100 kHz) |
| Pa | 3.15 | 2.9 | 0.08 | 0.05 |
| Pb | 3.23 | 3.09 | 0.08 | 0.03 |
| Pc | 3.59 | 3.36 | 0.08 | 0.04 |
| Pd | 3.32 | 3.22 | 0.07 | 0.03 |
| Pe | 3.15 | 2.86 | 0.10 | 0.01 |
| Pf | 3.91 | 3.63 | 0.13 | 0.02 |
| Pg | 3.11 | 3.06 | 0.01 | 0.01 |

### Example 4

### Preparation of a Top-Gate, Bottom-Contact (TGBC) Field Effect Transistors Comprising Polymers Pa, Pb, Pc, Pd, Pe, Pf and Pg, Respectively, as Dielectric Material

Gold was sputtered onto PET substrate to form approximately 40 nm thick gold source/drain electrodes. A 1% (weight/weight) solution of the diketopyrrolopyrrole semiconducting polymer of example 1 of WO2013/083506 in mesitylene was filtered through a 0.45 micrometer polytetrafluoroethylene (PTFE) filter and then applied by spin coating (1,000 rpm, 60 seconds). The wet organic semiconducting layer was dried at 120° C. on a hot plate for 60 seconds. Compositions comprising a dielectric polymer and a solvent as listed in table 3 were filtered with 0.7 μm filter and applied on the semiconductor by spin coating under the conditions mentioned in table 3. The wet dielectric layers were baked at 90° C. for 30 minutes after coating to obtain polymer layers with a thickness as indicated in table 3. Gate electrodes of gold (thickness approximately 70 nm) were evaporated through a shadow mask on the dielectric layer.

TABLE 3

| Composition | | | Spin coating | | Layer |
|---|---|---|---|---|---|
| | Polymer | | Spin-speed | Spin time | thickness |
| Polymer | [wt %]^{a} | Solvent | [rpm] | [s] | [nm] |
| Pa | 12 | butyl acetate | 1500 | 30 | 525 |
| Pb | 10 | butyl acetate | 1500 | 30 | 543 |
| Pc | 12 | butyl acetate | 1500 | 30 | 546 |
| Pd | 8 | butyl acetate | 1200 | 30 | 390 |
| Pe | 8 | butyl acetate | 1500 | 30 | 510 |
| Pf | 10 | butyl acetate | 1500 | 30 | 515 |
| Pg | 12 | PGMEA/CP | 1200 | 30 | 477 |
| | | 9/1 | | | |

^{a}based on the weight of the composition.
^{b}Propylene glycol methyl ether acetate/cyclopentanone.

The top-gate, bottom-contact (TGBC) field effect transistors were measured by using a Keithley semiconductor characterization system.

The drain current I_{d} in relation to the gate-source voltage V_{gs} (transfer curve) for the top-gate, bottom-contact (TGBC) field effect transistors at a drain-source voltage V_{ds} of −30 V is shown in FIG. 1 (for Pa), FIG. 2 (for Pb), FIG. 3 (for Pc), Figured (for Pd), FIG. 5 (for Pe), FIG. 6 (for Pf), and FIG. 7 (for Pg) respectively. The solid black line curve shows the drain current plotted on a logarithmic scale (left y-axis). The solid dark grey line shows the square root of drain current plotted on a linear scale (right y-axis). In addition, FIGS. 1 to 7 show the gate current plotted on a logarithmic scale (left y-axis) as light-grey, dotted line.

The charge-carrier mobility μ was calculated by using the following equation:

μ=m²×2L/(C_{G}×W) with C_{G}=K′×epsilon₀/d

wherein m is the slope of the square root drain current I_{d}^{1/2} extracted by a linear fit to the square root of the drain current in the transfer curves of FIGS. 1 to 7, L=10 μm is the channel length of the transistor, W=250 μm is the channel width of the transistor, and C_{G} is the area normalized capacitance, with epsilon₀ is the vacuum permittivity of 8.85×10⁻¹² F//m, K′ is the dielectric constant of the respective material measured at 20 Hz (see table 2) and d is the thickness of the dielectric polymer on top of the organic semiconductor (see table 3).

The threshold voltage Vth was calculated by using the following equation

Vth=−1×m/b

Wherein m is the slope of the square root drain current I_{ds}^{1/2} extracted from the transfer curves, and b is the y-axis intersection of the fitted curve.

The Ion/Ioff ratio was calculated by using the following equation:

Ion/Ioff=I_{D} max/I_{D} min

The average values of the charge-carrier mobility μ, the Iₒₙ/I_{off} ratio and the threshold voltage Vₜₕ for the organic field effect transistor taken from at least 10 TFTs are given in table 4.

TABLE 4

| | charge carrier mobility μ | | Vₜₕ |
|---|---|---|---|
| Polymer | [cm²/Vs] | Iₒₙ/I_{off} | [V] |
| Pa | 0.69 | 6E4 | 1 |
| Pb | 0.56 | 6E4 | 1 |
| Pc | 0.47 | 3E4 | 1 |
| Pd | 0.47 | 1E5 | 0.5 |
| Pe | 0.56 | 7E5 | 0 |
| Pf | 0.44 | 1E5 | 0.5 |
| Pg | 0.52 | 1E5 | 0.5 |

### Comparative Example 1

### Preparation of a Top-Gate, Bottom-Contact (TGBC) Field Effect Transistors Comprising Polystyrene as Dielectric Material

A top-gate, bottom contact (TGBC) field effect transistor was prepared in analogy to example 4, but comprising polystyrene (MW 2,000,000 g/mol) instead of Pa as dielectric material, and measured by using a Keithley semiconductor characterization system in analogy to example 4.

FIG. 8 shows the of drain current plotted on a linear scale (left y-axis) for the transistor of example 4 comprising Pa as dielectric material and of the transistor of comparative example 1 comprising polystyrene as dielectric material.

FIG. 8 shows that a higher drain current can be achieved using the field effect transistor of example 4 comprising Pa as dielectric material at a specific gate-source voltage (operational voltage) compared to using the field effect transistor comprising polystyrene as dielectric material. Or in other words, a specific drain current can be achieved using the field effect transistor of example 4 comprising Pa as dielectric material at a lower specific gate-source voltage (operational voltage) compared to using the field effect transistor comprising polystyrene as dielectric material.

1. Polymers comprising units of formula (1) 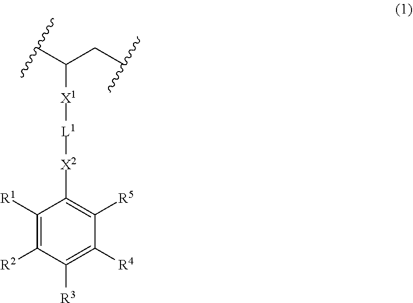
wherein
X¹ and X² are independently O or S,
L¹ is a linking group, and
R¹, R², R³, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, C(O)—C₆₋₁₄-aryl substituted with one or more substituents R^{b}, 5 to 14 membered heteroaryl and 5 to 14 membered heteroaryl substituted with one or more substituents R^{b},
or
R¹ and R² together with the C-atoms to which they are attached form a 5 to 6 membered ring or a 5 to 6 membered ring substituted with one or more substituents R^{c}, and
R³, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, C(O)—C₆₋₁₄-aryl substituted with one or more substituents R^{b}, 5 to 14 membered heteroaryl and 5 to 14 membered heteroaryl substituted with one or more substituents R^{b},
or
R² and R³ together with the C-atoms to which they are attached form a 5 to 6 membered ring or a 5 to 6 membered ring substituted with one or more substituents R^{c}, and
R¹, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, C(O)—C₆₋₁₄-aryl substituted with one or more substituents R^{b}, 5 to 14 membered heteroaryl and 5 to 14 membered heteroaryl substituted with one or more substituents R^{b},
or
R³ and R⁴ together with the C-atoms to which they are attached form a 5 to 6 membered ring or a 5 to 6 membered ring substituted with one or more substituents R^{c}, and
R¹, R² and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, C(O)—C₆₋₁₄-aryl substituted with one or more substituents R^{b}, 5 to 14 membered heteroaryl and 5 to 14 membered heteroaryl substituted with one or more substituents R^{b},
or
R⁴ and R⁵ together with the C-atoms to which they are attached form a 5 to 6 membered ring or a 5 to 6 membered ring substituted with one or more substituents R^{c}, and
R¹, R² and R³ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a}, C₅₋₇-cycloalkyl, C₅₋₇-cycloalkyl substituted with one or more substituents R^{b}, O—C₅₋₇-cycloalkyl, O—C₅₋₇-cycloalkyl substituted with one or more substituents R^{b}, C(O)—C₅₋₇-cycloalkyl, C(O)—C₅₋₇-cycloalkyl substituted with one or more substituents R^{b}, C₆₋₁₄-aryl, C₆₋₁₄-aryl substituted with one or more substituents R^{b}, O—C₆₋₁₄-aryl, O—C₆₋₁₄-aryl substituted with one or more substituents R^{b}, C(O)—C₆₋₁₄-aryl, C(O)—C₆₋₁₄-aryl substituted with one or more substituents R^{b}, 5 to 14 membered heteroaryl and 5 to 14 membered heteroaryl substituted with one or more substituents R^{b},
wherein
R^{a} is at each occurrence selected from the group consisting of O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, C(O)-phenyl and 5 to 9 membered heteroaryl, and
R^{b} and R^{c} are independently and at each occurrence selected from the group consisting of C₁₋₂₀-alkyl, O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, C(O)-phenyl and 5 to 9 membered heteroaryl.

2. The polymers of claim 1, wherein X¹ and X² are O.

3. The polymers of claim 1, wherein L¹ is a linking group which is C₁₋₃₀-alkylene.

4. The polymers of any of claim 1, wherein R¹, R², R³, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, and C(O)—C₁₋₃₀-alkyl substituted with one or more substituents R^{a},
or
R¹ and R² together with the C-atoms to which they are attached form a 5 to 6 membered aromatic ring or a 5 to 6 membered aromatic ring substituted with one or more substituents R^{c}, and
R³, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, and C(O)—C₁₋₃₀-alkyl substituted with one or more substituents R^{a},
or
R² and R³ together with the C-atoms to which they are attached form a 5 to 6 membered aromatic ring or a 5 to 6 membered aromatic ring substituted with one or more substituents R^{c}, and
R¹, R⁴ and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, and C(O)—C₁₋₃₀-alkyl substituted with one or more substituents R^{a},
or
R³ and R⁴ together with the C-atoms to which they are attached form a 5 to 6 membered aromatic ring or a 5 to 6 membered aromatic ring substituted with one or more substituents R^{c}, and
R¹, R² and R⁵ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a},
or
R⁴ and R⁵ together with the C-atoms to which they are attached form a 5 to 6 membered aromatic ring or a 5 to 6 membered aromatic ring substituted with one or more substituents R^{c}, and
R¹, R² and R³ are independently selected from the group consisting of H, C₁₋₃₀-alkyl, C₁₋₃₀-alkyl substituted with one or more substituents R^{a}, O—C₁₋₃₀-alkyl, O—C₁₋₃₀-alkyl substituted with one or more substituents R^{a}, C(O)—C₁₋₃₀-alkyl, C(O)—C₁₋₃₀-alkyl substituted with one or more substituents R^{a},
wherein
R^{a} is at each occurrence selected from the group consisting of O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, and C(O)-phenyl, and
R^{c} is at each occurrence selected from the group consisting of C₁₋₂₀-alkyl, O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, and C(O)-phenyl.

5. The polymers of claim 4, wherein
R¹, R², R³, R⁴ and R⁵ are independently selected from the group consisting of H, C₁₋₁₀-alkyl and O—C₁₋₁₀-alkyl,
or
R¹ and R² together with the C-atoms to which they are attached form an aromatic 6-membered aromatic ring, which is 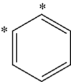
wherein the C-atoms marked with * are the C-atoms to which R¹ and R² are attached, and
R³, R⁴ and R⁵ are independently selected from the group consisting of H, C₁₋₁₀-alkyl and O—C₁₋₁₀-alkyl,
or
R² and R³ together with the C-atoms to which they are attached form an aromatic 6-membered aromatic ring, which is 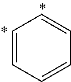
wherein the C-atoms marked with * are the C-atoms to which R² and R³ are attached, and R¹, R⁴ and R⁵ are independently selected from the group consisting of H, C₁₋₁₀-alkyl and O—C₁₋₁₀-alkyl,
or
R³ and R⁴ together with the C-atoms to which they are attached form an aromatic 6-membered aromatic ring, which is 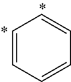
wherein the C-atoms marked with * are the C-atoms to which R³ and R⁴ are attached, and
R¹, R² and R⁵ are independently selected from the group consisting of H, C₁₋₁₀-alkyl and O—C₁₋₁₀-alkyl,
or
R⁴ and R⁵ together with the C-atoms to which they are attached form an aromatic 6-membered aromatic ring, which is 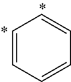
wherein the C-atoms marked with * are the C-atoms to which R⁴ and R⁵ are attached, and R¹, R², and R³ are independently selected from the group consisting of H, C₁₋₁₀-alkyl and O—C₁₋₁₀-alkyl.

6. The polymers of claim 1 also comprising units of formula (2) 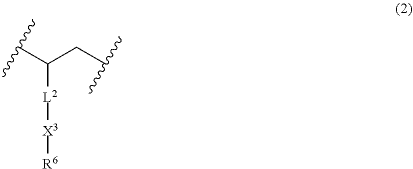
wherein
X³ is independently O or S,
L² is a covalent bond or a linking group,
R⁶ is independently selected from the group consisting of H, C₁₋₃₀-alkyl, C₁₋₃₀-alkyl substituted with one or more substituents R^{d}, C₅₋₇-cycloalkyl, C₅₋₇-cycloalkyl substituted with one or more substituents R^{e}, C₆₋₁₄-aryl, C₆₋₁₄-aryl substituted with one or more substituents R^{e}, 5 to 14 membered heteroaryl and 5 to 14 membered heteroaryl substituted with one or more substituents R^{e},
wherein
R^{d} is at each occurrence selected from the group consisting of O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, C(O)-phenyl and 5 to 9 membered heteroaryl, and
R^{e} is at each occurrence selected from the group consisting of C₁₋₂₀-alkyl, O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, C(O)-phenyl and 5 to 9 membered heteroaryl.

7. The polymers of claim 6, wherein X³ is O.

8. The polymers of claim 6, wherein L² is a covalent bond or a linking group, which is phenylene.

9. The polymers of claim 6, wherein
R⁶ is independently selected from the group consisting of H, C₁₋₃₀-alkyl, C₁₋₃₀-alkyl substituted with one or more substituents R^{d}, C₅₋₇-cycloalkyl, and C₅₋₇-cycloalkyl substituted with one or more substituents R^{e}, wherein
R^{d} is at each occurrence selected from the group consisting of O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, and O-phenyl, C(O)-phenyl, and
R^{e} is at each occurrence selected from the group consisting of C₁₋₂₀-alkyl, O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, and C(O)-phenyl.

10. The polymers of claim 9, wherein
R⁶ is independently selected from the group consisting of H, C₁₋₁₀-alkyl and C₅₋₇-cycloalkyl.

11. The polymer of claim 6 comprising at least 80 mol % units of formula (1) and (2) based on the mols of all repeating units of the polymer.

12. A process for the preparation of the polymers of claim 1 comprising units of formula (1) 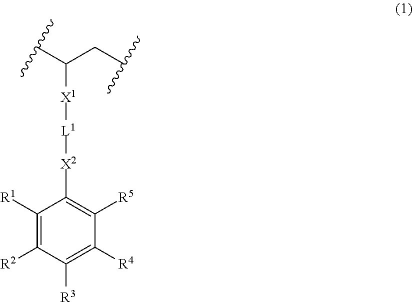
wherein
X¹ and X², L¹ and R¹, R², R³, R⁴ and R⁵ are as defined in claim 1, which process comprises the step of polymerizing monomers including the compound of formula (3) 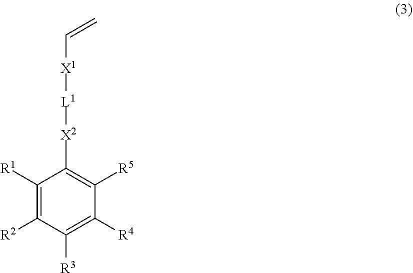
wherein
X¹, X², L¹, R¹, R², R³, R⁴ and R⁵ are as defined for a compound of formula (1),
in order to yield the polymers of claim 1.

13. A process of claim 12 for the preparation of the polymers comprising units of formula (1) and (2) 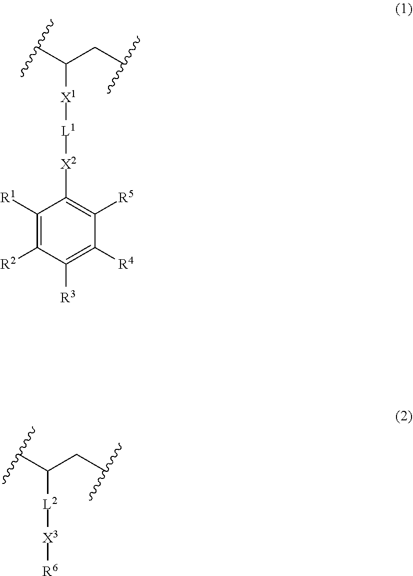
wherein
X¹, X², L¹, R¹, R², R³, R⁴ and R⁵ are as defined in claim 12, and
X³ is independently O or S,
L² is a covalent bond or a linking group,
R⁶ is independently selected from the group consisting of H, C₁₋₃₀-alkyl, C₁₋₃₀-alkyl substituted with one or more substituents R^{d}, C₅₋₇-cycloalkyl, C₅₋₇-cycloalkyl substituted with one or more substituents R^{e}, C₆₋₁₄-aryl, C₆₋₁₄-aryl substituted with one or more substituents R^{e}, 5 to 14 membered heteroaryl and 5 to 14 membered heteroaryl substituted with one or more substituents R^{e},
wherein
R^{d} is at each occurrence selected from the group consisting of O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, C(O)-phenyl and 5 to 9 membered heteroaryl, and
R^{e} is at each occurrence selected from the group consisting of C₁₋₂₀-alkyl, O—C₁₋₂₀-alkyl, C(O)—C₁₋₂₀-alkyl, C₅₋₆-cycloalkyl, O—C₅₋₆-cycloalkyl, C(O)—C₅₋₆-cycloalkyl, phenyl, O-phenyl, C(O)-phenyl and 5 to 9 membered heteroaryl,
which process comprises the step of polymerizing monomers including a compound of formula (3) and a compound of formula (4) 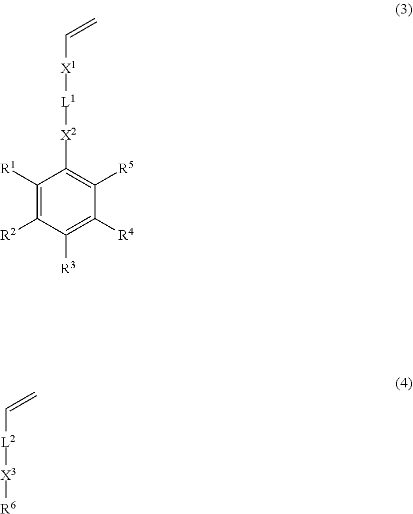
wherein
X¹, X², L¹, R¹, R², R³, R⁴ and R⁵ are as defined for a unit of formula (1), and X³, L² and R⁶ are as defined for a unit of formula (2),
in order to yield the polymers comprising units of formula (1) and (2).

14. A composition comprising at least one polymer of claim 1 and a solvent.

15. The composition of claim 14, also comprising a crosslinking agent.

16. An electronic device comprising a layer i) comprising the polymers of claim 1, or ii) formed from the composition comprising the above mentioned polymers and a solvent.

17. The electronic device of claim 16, which is a field effect transistor.

18. A process for the preparation of the field effect transistor of claim 17, which comprises the steps of applying the composition on a precursor of the field effect transistor, removing the solvent of the composition and forming a dielectric layer.

19. Use of the polymers of claim 1 as dielectric material.
